(19) United States
(12) Patent Application Publication
(10) Pub. No.: US 2025/0374756 A1
(43) Pub. Date: Dec. 4, 2025

(54) METHOD FOR MANUFACTURING DISPLAY DEVICE AND DISPLAY ELEMENT

(71) Applicant: Samsung Display Co., LTD., Yongin-si (KR)

(72) Inventors: Woo Jong SON, Yongin-si (KR); Kyoung Tae KIM, Yongin-si (KR); Chang Min PARK, Yongin-si (KR); Yong Kwon SOH, Yongin-si (KR)

(73) Assignee: Samsung Display Co., LTD., Yongin-si (KR)

(21) Appl. No.: 18/985,668

(22) Filed: Dec. 18, 2024

(30) Foreign Application Priority Data
May 30, 2024 (KR) 10-2024-0070946

(51) Int. Cl. H10K 59/12; H10K 59/80; H10K 102/00

(52) U.S. Cl. CPC H10K 59/1201; H10K 59/80; H10K 2102/311

(57) ABSTRACT

Provided are a method for manufacturing display device and a display element. A method for manufacturing a display device, the method includes, attaching a panel support film onto a display panel including a bending area, removing a portion of the panel support film, which is disposed in the bending area, and attaching an adhesive film onto the panel support film, wherein the adhesive film includes an adhesive layer and a liner disposed on the adhesive layer.

### CROSS-REFERENCE TO RELATED APPLICATION

This application claims priority to and benefits of Korean Patent Application No. 10-2024-0070946 under 35 U.S.C. § 119, filed on May 30, 2024, in the Korean Intellectual Property Office, the entire contents of which are incorporated herein by reference.

### BACKGROUND

### 1. Technical Field

The disclosure relates to a method for manufacturing a display device and a display element.

### 2. Description of the Related Art

With the advancement of the information age, the demand for a display device for displaying an image has increased with various forms. The display device may be a display device such as a liquid crystal display device, a field emission display device and a light emitting display device. The light emitting display device may include an organic light emitting display device that includes an organic light emitting diode element as a light emitting element or an inorganic light emitting display device that includes an inorganic light emitting diode element as a light emitting element.

The display device may include a display module disposed on a substrate. The substrate of the display device may be electrically connected to a circuit board for providing driving signals. Pads for electric connection to the circuit board and other components may be arranged in a non-display area of the substrate. When the display area is intended to be disposed on an entire surface of the display device, it is necessary to minimize the non-display area in which the pads and other components are arranged. Recently, efforts for reducing a size of the non-display area of the display device by bending a portion of the substrate are ongoing.

### SUMMARY

An object of the disclosure is to provide a method for manufacturing a display device and a display element, in which manufacturing process efficiency of the display device is improved.

The objects of the disclosure are not limited to those mentioned above and additional objects of the disclosure, which are not mentioned herein, will be clearly understood by those skilled in the art from the following description of the disclosure.

According to an aspect of the disclosure, there is provided a method for manufacturing a display device, the method including, attaching a panel support film onto a display panel including a bending area, removing a portion of the panel support film, which is disposed in the bending area, and attaching an adhesive film onto the panel support film, wherein the adhesive film includes an adhesive layer and a liner disposed on the adhesive layer.

In an embodiment, the panel support film includes a first opening disposed in the bending area, and the adhesive layer does not overlap the first opening in a thickness direction.

In an embodiment, a side of the first opening is an inclined surface.

In an embodiment, the method may further comprise cutting a display cell including the display panel, wherein the cutting of the display cell is performed before the attaching of the panel support film, and an end of the adhesive layer is positioned more inward than an end of the display panel.

In an embodiment, the method may further comprise cutting a display cell including the display panel, wherein the cutting of the display cell is performed after the attaching of the adhesive film, and a boundary of an end of the adhesive layer is aligned with a boundary of an end of the display panel.

In an embodiment, the attaching of the adhesive film is performed before the removing of the portion of the panel support film, which is disposed in the bending area, and the adhesive layer is removed together with the panel support film when the removing of the portion of the panel support film, which is disposed in the bending area.

An electronic device comprising a display device manufactured by the method. According to an aspect of the disclosure, there is provided a method for manufacturing a display device, the method including, manufacturing a display panel, and attaching a module to the display panel, wherein the manufacturing of the display panel includes attaching a panel support film onto the display panel and attaching an adhesive film onto the panel support film, and the attaching of the module to the display panel includes attaching a lower functional member onto the adhesive film.

In an embodiment, the adhesive film includes an adhesive layer and a liner disposed on the adhesive layer, and the liner is removed when the attaching of the lower functional member.

In an embodiment, the attaching of the panel support film and the attaching of the adhesive film, which are included in a first process, are performed in a continuous process.

In an embodiment, the attaching of the panel support film and the attaching of the adhesive film, which are included in the first process, are performed in a clean room.

In an embodiment, the manufacturing of the display panel and the attaching of the module to the display panel are performed in different spaces.

In an embodiment, the first process and the second process are performed by different subjects.

An electronic device comprising a display device manufactured by the method.

According to an aspect of the disclosure, there is provided a display element including, a display panel including a bending area, a panel support film disposed on the display panel, an adhesive layer disposed on the panel support film, and a liner disposed on the adhesive layer, wherein boundaries of an end of the panel support film, an end of the adhesive layer and an end of the liner are aligned with one another.

In an embodiment, the panel support film includes a first opening disposed in the bending area, and the adhesive layer does not overlap the first opening in a thickness direction.

In an embodiment, a side of the first opening is an inclined surface.

In an embodiment, the liner overlaps the first opening in the thickness direction.

In an embodiment, the adhesive layer includes a second opening communicated with the first opening, a first portion disposed on a side of the second opening, and a second portion disposed on another side of the second opening.

In an embodiment, a side of the second opening is an inclined surface.

In an embodiment, the liner includes a third opening communicated with the second opening, a third portion disposed on a side of the third opening, and a fourth portion disposed on another side of the third opening.

In an embodiment, the adhesive layer is disposed on a side of the first opening, and is not disposed on another side of the first opening.

In the method for manufacturing a display device and the display element according to one embodiment, manufacturing process efficiency of the display device may be improved.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1A is a schematic plan view illustrating a display device according to one embodiment;

FIG. 1B is a schematic plan view illustrating a display device according to another embodiment;

FIG. 2 is a schematic cross-sectional view illustrating a display device taken along line X1-X1′ of FIG. 1;

FIG. 3 is a schematic cross-sectional view illustrating a state that the display device of FIG. 2 is bent;

FIG. 4 is a schematic plan view illustrating lines and pads of a display device according to one embodiment;

FIG. 5 is a schematic cross-sectional view illustrating a display device taken along line X1-X1′ of FIG. 1;

FIG. 6 is a schematic cross-sectional view illustrating a display panel according to one embodiment;

FIG. 7 is a schematic flow chart illustrating a method for manufacturing a display device according to one embodiment;

FIG. 8 is a schematic plan view illustrating step S110 of FIG. 7;

FIG. 9 is a schematic cross-sectional view taken along line X2-X2′ of FIG. 8 to illustrate step S110 of FIG. 7;

FIG. 10 is a schematic plan view illustrating step S120 of FIG. 7;

FIG. 11 is a schematic cross-sectional view taken along line X3-X3′ of FIG. 10 to illustrate step S120 of FIG. 7;

FIG. 12 is a schematic cross-sectional view taken along line X3-X3′ of FIG. 10 to illustrate step S130 of FIG. 7;

FIG. 13 is a schematic cross-sectional view taken along line X3-X3′ of FIG. 10 to illustrate step S140 of FIG. 7;

FIG. 14 is a schematic cross-sectional view taken along line X3-X3′ of FIG. 10 to illustrate step S150 of FIG. 7;

FIG. 15 is a schematic flow chart illustrating step S150 of FIG. 7;

FIGS. 16 and 17 are schematic cross-sectional views illustrating step S151 of FIG. 15;

FIG. 18 is a schematic cross-sectional view illustrating step S152 of FIG. 15;

FIG. 19 is a schematic flow chart illustrating step S150′ of a method for manufacturing a display device according to a comparative embodiment;

FIG. 20 is a schematic cross-sectional view illustrating step S151a′ of a method for manufacturing a display device according to a comparative embodiment;

FIG. 21 is a schematic view illustrating a method for manufacturing a display device according to a comparative embodiment;

FIG. 22 is a schematic view illustrating a method for manufacturing a display device according to one embodiment;

FIG. 23 is a schematic flow chart illustrating a method for manufacturing a display device according to another embodiment;

FIG. 24 is a schematic plan view illustrating step S210 of FIG. 23;

FIG. 25 is a schematic perspective view illustrating step S240 of FIG. 23;

FIG. 26 is a schematic cross-sectional view illustrating step S240 of FIG. 23;

FIG. 27 is a schematic cross-sectional view illustrating step S250 of FIG. 23;

FIG. 28 is a schematic flow chart illustrating a method for manufacturing a display device according to another embodiment;

FIG. 29 is a schematic cross-sectional view illustrating step S310 of FIG. 28;

FIG. 30 is a schematic cross-sectional view illustrating step S350 of FIG. 28;

FIG. 31 is a schematic block diagram of an electronic device according to an embodiment; and

FIG. 32 is a schematic diagram of an electronic device according to various embodiments.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

In the entire specification, in case that an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that in case that a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

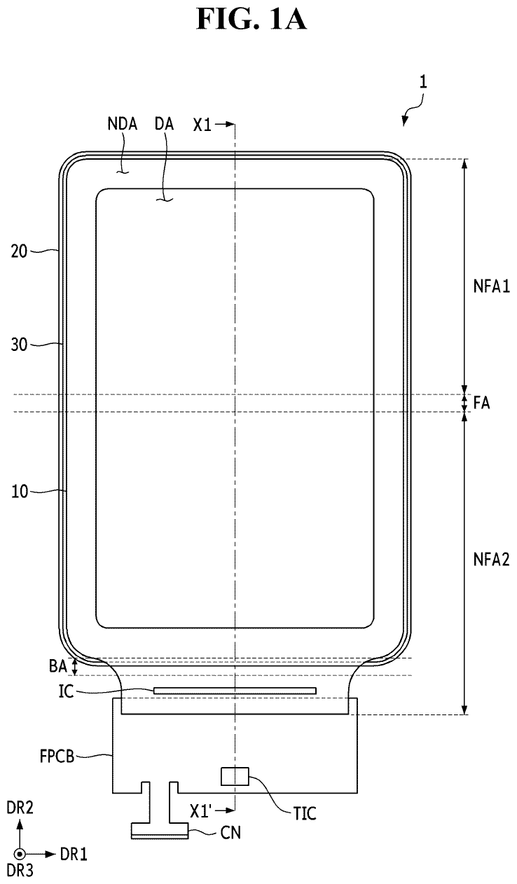

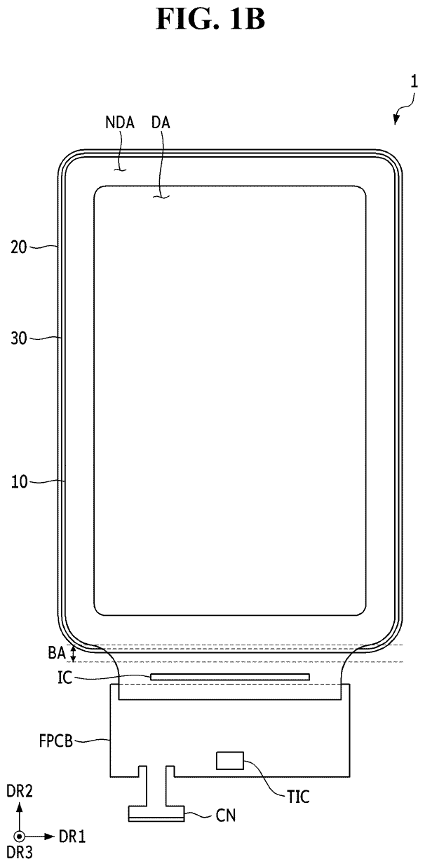

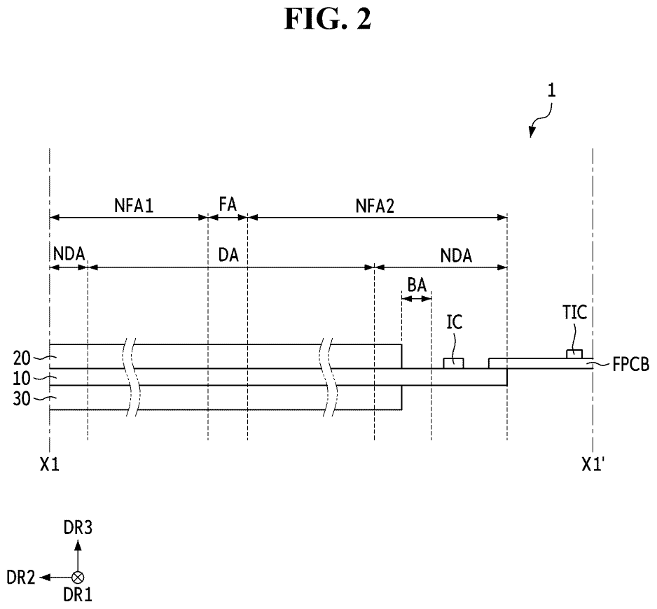

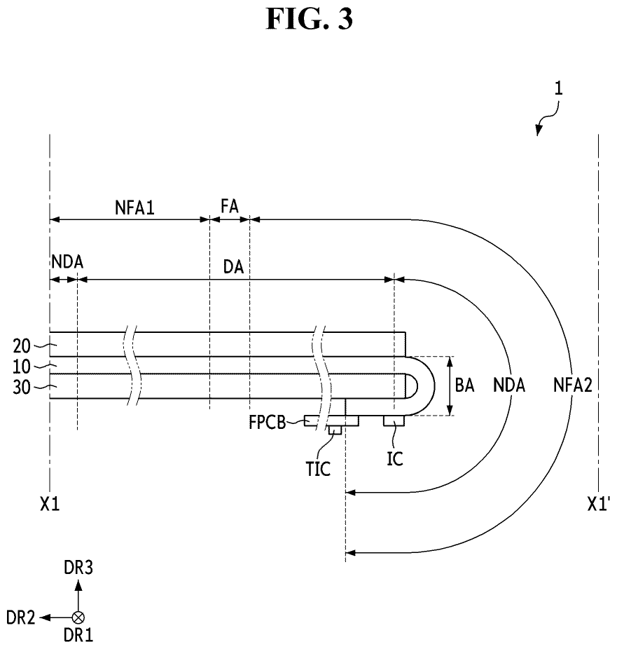

FIG. 1A is a schematic plan view illustrating a display device according to one embodiment. FIG. 1B is a schematic plan view illustrating a display device according to another embodiment. FIG. 2 is a schematic cross-sectional view illustrating a display device taken along line X1-X1′ of FIG. 1A. FIG. 3 is a schematic cross-sectional view illustrating a state that the display device of FIG. 2 is bent.

Referring to FIGS. 1A, 1B, 2 and 3, a display device 1 may display a screen or an image through a display area DA. The display device 1 may include various devices that include the display area DA. For example, the display device 1 may include a smart phone, a cellular phone, a tablet PC, a personal digital assistant (PDA), a portable multimedia player (PMP), a television, a game machine, a wrist watch type electronic device, a head mounted display, a monitor of a personal computer, a laptop computer, a vehicle navigator, a vehicle dashboard, a digital camera, a camcorder, an external advertisement board, an electronic display board, various medical devices, various inspection devices, various home appliances including a display area DA, such as a refrigerator and a washing machine, a device for Internet of Things (IoT), etc. A main example of a foldable display device, which will be described later, include a foldable smart phone, a tablet PC or a laptop, but is not limited thereto.

The display device 1 may be formed in a substantially rectangular shape in a plan view. The display device 1 may have a rectangular shape having vertical corners or a rectangular shape having rounded corners in a plan view. The description will be based on that a planar shape of the display device 1 includes a rectangular shape having rounded corners, but is not limited thereto.

The display device 1 may include four sides and four edges. The number of sides and edges of the display device 1 is not limited thereto. The display device 1 may include long sides and short sides.

The short sides of the display device 1 may be extended in a direction, and the long sides of the display device 1 may be extended in the another direction. For example, the short sides of the display device 1 may be extended in a first direction DR1, and the long sides of the display device 1 may be extended in a second direction DR2.

In the drawing, the first and second directions DR1 and DR2 are horizontal directions and cross each other. For example, the first direction DR1 and the second direction DR2 may be orthogonal to each other. A third direction DR3 crosses the first and second directions DR1 and DR2, and may be, for example, a vertical direction orthogonal thereto. Unless defined otherwise, in the disclosure, directions indicated by arrows in the first to third directions DR1, DR2 and DR3 may be referred to as as, and their opposite directions may be referred to as another side. Also, in the disclosure, “upper”, “upper side”, “upper portion”, and “upper surface” refer to a direction toward which the arrow in the third direction DR3 is directed based on the drawing, and “lower”, “lower side”, “lower portion”, and “lower surface” refer to an opposite direction of a direction toward which the arrow in the third direction DR3 is directed based on the drawing.

The display device 1 may include a display panel 10 for displaying an image, an upper stacked structure 20, a lower stacked structure 30, and an external device attached to the display panel 10. The external device may include a driving chip IC, a printed circuit film FPCB and a touch driving chip TIC.

The display panel 10 is a panel for displaying a screen or an image, and its examples may include light receiving display panels such as a liquid crystal display panel and an electrophoretic display panel as well as self-light emitting display panels such as an organic light emitting display panel, an inorganic light emitting display panel, a quantum dot light emitting display panel, a micro LED display panel, a nano LED display panel, a plasma display panel, a field emission display panel and a cathode-ray display panel.

An organic light emitting display panel will be described as the display panel 10 by way of example, and the organic light emitting display panel applied to the embodiments will be simply abbreviated as the display panel 10 unless a special distinction is required. However, the embodiments are not limited to the organic light emitting display panel, and other display panels 10 listed above or known in the art may be applied in the range that share the technical spirits.

The display panel 10 may include a surface (or an upper surface) and another surface (or a lower surface). Based on the display device 1, a direction from the other surface toward one surface of the display panel 10 may be a display direction and a direction from one surface toward the other surface of the display panel 10 may be a direction in which display is not performed, but the disclosure is not limited thereto. The direction from the other surface toward one surface of the display panel 10 and the direction from one surface toward the other surface of the display panel 10 may be all display directions.

In other embodiments, the display device 1 may be a foldable device. The foldable device is a device that may be folded, and is used to include not only a folded device but also a device capable of having both a folding state and an unfolding state. The above-described folding state will be referred to as a first operation state and the above-described unfolding state will be referred to as a second operation state.

The display panel 10 may include a folding area FA (or a folding axis) and non-folding areas NFA1 and NFA2. The display panel 10 may be folded based on the folding area FA (or the folding axis) at the second operation state and then modified to the first operation state.

The folding area FA may have a linear shape extended in the first direction DR1 in a plan view. Although the case that the folding area FA is extended in parallel with the short side of the display device 1 is illustrated in the drawing, the disclosure is not limited thereto. The folding area FA may be parallel with the long side or may be inclined with respect to the short side and the long side.

The first non-folding area NFA1 and the second non-folding area NFA2 may be areas that are not folded. The first non-folding area NFA1 may be positioned on a side of the folding area FA in the second direction DR2, and the second non-folding area NFA2 may be positioned on another side of the folding area FA in the second direction DR2.

The display panel 10 may include a display area DA for displaying a picture or an image and a non-display area NDA for not displaying a picture or an image depending on whether an image is displayed.

The display area DA may include multiple pixels. The pixel may be a basic unit for displaying a screen. The pixel may, but is not limited to, include a red pixel, a green pixel and a blue pixel. The pixel may further include a white pixel. Multiple pixels may be alternately arranged in a plan view. For example, the pixel may be disposed in a matrix direction, but is not limited thereto.

The non-display area NDA may be disposed near the display area DA. The non-display area NDA may surround the display area DA. The display area DA may be formed in a rectangular shape, and the non-display area NDA may be disposed around four sides of the display area DA.

The rectangular shape of the display area DA may include, for example, short sides extended in the first direction DR1 and long sides extended in the second direction DR2. The non-display area NDA may be disposed near the short sides and the long sides of the display area DA. A black matrix may be disposed on the non-display area NDA of the display panel 10 to prevent light emitted from adjacent pixels from leaking.

The display area DA of the display panel 10 may be disposed over both the first non-folding area NFA1 and the second non-folding area NFA2. Furthermore, the display area DA may be also positioned in the folding area FA corresponding to a boundary between the first non-folding area NFA1 and the second non-folding area NFA2. For example, the display area DA of the display device 1 may be continuously disposed regardless of the boundaries of the non-folding areas NFA1 and NFA2, the folding area FA and the like, but the disclosure is not limited thereto. The display area DA may be disposed in the first non-folding area NFA1 but may not be disposed in the second non-folding area NFA2. The display area DA may be disposed in the first non-folding area NFA1 and the second non-folding area NFA2, but the non-display area NDA may not be disposed in the folding area FA.

In the same manner as the display area DA, the non-display area NDA may be also positioned in the first non-folding area NFA1, the second non-folding area NFA2 and the folding area FA.

In other embodiments, the display device 1 may be folded in an in-folding manner, in which a surface of the display panel 10 is folded so that the folded surfaces face each other, at the first operation state. At the first operation state, a surface of the first non-folding area NFA1 of the display panel 10 may be folded to face a surface of the second non-folding area NFA2.

In other embodiments, the display device 1 may be folded in an out-folding manner, in which another surface of the display panel 10 is folded so that the folded surfaces face each other, at the first operation state. At the first operation state, another surface of the first non-folding area NFA1 of the display panel 10 may be folded to face another surface of the second non-folding area NFA2.

The display device 1 may be folded only in one of the in-folding manner and the out-folding manner, or may be folded in both the in-folding manner and the out-folding manner. In case of the display device 1 in which both in-folding and out-folding are performed, in-folding and out-folding may be performed based on the same folding area FA, or the display device 1 may include multiple folding areas FA in which different types of folding are performed such as an in-folding-only folding line and an out-folding-only folding line.

The non-display area NDA adjacent to another short side of the display area DA in the second direction DR2 may further include a protrusion protruded toward another side in the second direction DR2. A width of the protrusion in the first direction DR1 may be smaller than that of the non-display area NDA in the first direction DR1, which is positioned on a side of the protrusion in the second direction DR2. The width of the protrusion in the first direction DR1 may be gradually reduced toward another side in the second direction DR2, but is not limited thereto.

The protrusion may include a bending area BA. The bending area BA may have a line shape extended in the first direction DR1. The display panel 10 may be bent in a third direction DR3 (e.g., thickness direction) in the bending area BA of the non-display area NDA. As the display panel 10 is bent based on the bending area BA, another surfaces of the display panel 10 may face each other.

The external device may be attached to another side of the bending area BA of the protrusion in the second direction DR2. An attachment position of the driving chip IC may be positioned between an attachment position of the printed circuit film FPCB and the bending area BA. At the second operation state, the driving chip IC may be positioned between the printed circuit film FPCB and the display area DA or between the printed circuit film FPCB and the bending area BA in a plan view.

The driving chip IC may include a driving integrated circuit to apply a data voltage and control application of the data voltage and/or application of a scan signal to each pixel. Multiple driving pads may be disposed at the attachment position of the driving chip IC in the non-display area NDA, and the driving chip IC may be attached to multiple driving pads. For example, the driving chip IC may be a display driver.

The printed circuit film FPCB may provide a data voltage signal, a data voltage application control signal and/or a scan signal application control signal to the driving chip IC. The printed circuit film FPCB may provide a high voltage potential signal and a low voltage potential signal to each pixel.

The printed circuit film FPCB may further include a connector CN positioned on the other end in the second direction DR2. The connector CN may be electrically connected to a main circuit board.

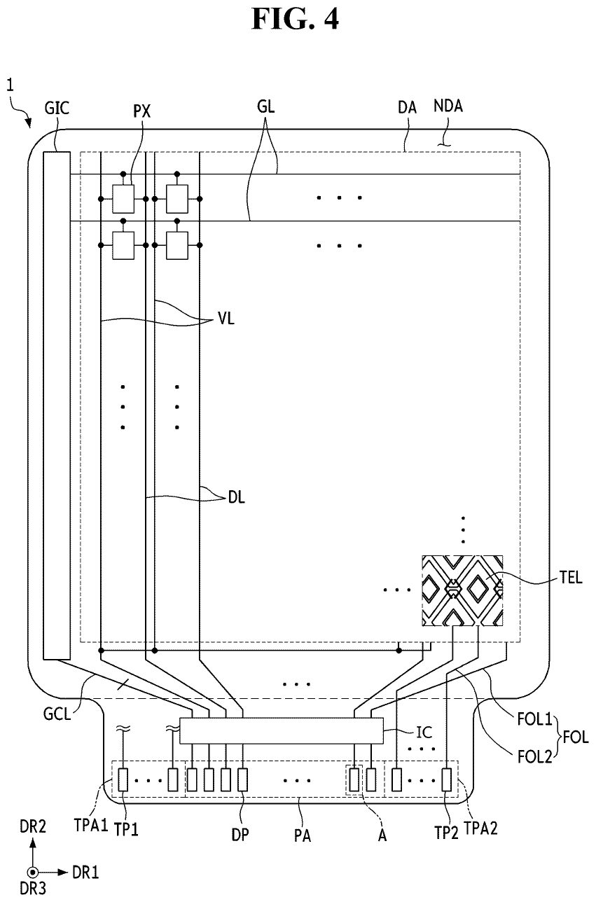

The touch driving chip TIC may be packaged on the printed circuit film FPCB. The touch driving chip TIC may be electrically connected to a touch sensing unit of the display panel 10. The touch driving chip TIC may supply a touch driving signal to multiple touch electrodes TEL (see FIG. 4) of the touch sensing unit, and may sense a change amount of capacitance between multiple touch electrodes. For example, the touch driving signal may be a pulse signal having a predetermined frequency. The touch driving chip TIC may calculate whether to input and input coordinates based on the change amount of capacitance between multiple touch electrodes. The touch driving chip TIC may be formed of an integrated circuit.

As shown in FIG. 2, the upper stacked structure 20 may be disposed on a surface of the display panel 10, and the lower stacked structure 30 may be disposed on another surface of the display panel 10. The upper stacked structure 20 and the lower stacked structure 30 may overlap another portions of the display panel 10 except the protrusion in the third direction DR3.

In FIGS. 1A and 1B, planar sizes of the upper stacked structure 20 and the lower stacked structure 30 are shown as being larger than those of the other portions of the display panel 10 except the protrusion, but are not limited thereto. Each of the planar sizes of the upper stacked structure 20 and the lower stacked structure 30 may be the same as that of the display panel 10, or may be smaller than that of the display panel 10.

As shown in FIG. 2, the upper stacked structure 20 and the lower stacked structure 30 may be disposed over the display area DA and the non-display area NDA of the display panel 10. The upper stacked structure 20 and the lower stacked structure 30 may be disposed over the folding area FA and the non-folding areas NFA1 and NFA2.

As shown in FIG. 3, in case that the display device 1 is bent based on the bending area BA, the other surfaces of the display panel 10 may be bent to face each other. The driving chip IC and the printed circuit film FPCB may be disposed to overlap the lower stacked structure 30 in the third direction DR3 (e.g., thickness direction). For example, the driving chip IC and the printed circuit film FPCB may be disposed on a lower portion of the lower stacked structure 30.

In other embodiments, as shown in FIG. 1B, the display device 1 may be a rigid device. In the disclosure, the rigid device is a device that cannot be folded in the display area DA, and is used as a meaning of including a bar-shaped display device. In case that the display device 1 is a rigid device, the display device 1 may not include the folding area FA and the non-folding areas NFA1 and NFA2.

Hereinafter, although the case that the display device 1 is the foldable device shown in FIG. 1A will be described as an example, but the disclosure is not limited thereto. The following description may be applied equally to even the case that the display device 1 is a rigid device in the same technical spirits that may be understood by a person skilled in the art.

FIG. 4 is a schematic plan view illustrating lines and pads of a display device according to one embodiment.

Referring to FIG. 4, the display area DA may be positioned approximately at the center of the display panel 10. Multiple pixels PX, multiple gate lines GL, multiple data lines DL, multiple power lines VL and multiple touch electrodes TEL may be disposed in the display area DA. Each of multiple pixels PX may be defined as a minimum unit for emitting light.

Multiple gate lines GL may supply a gate signal received from a gate driver GIC to multiple pixels PX. Multiple gate lines GL may be extended in the first direction DR1, and may be spaced apart from each other in the second direction DR2 crossing the first direction DR1.

Multiple data lines DL may supply the data voltage received from the driving chip IC to multiple pixels PX. Multiple data lines DL may be extended in the second direction DR2, and may be spaced apart from each other in the first direction DR1.

Multiple power lines VL may supply a power voltage received from the driving chip IC to multiple pixels PX. For example, the power voltage may be at least one of a driving voltage, an initialization voltage, a reference voltage or a low potential voltage. Multiple power lines VL may be extended in the second direction DR2, and may be spaced apart from each other in the first direction DR1.

Multiple touch electrodes TEL may form mutual capacitance to sense a touch of a person or an object. Multiple touch electrodes TEL may include multiple driving electrodes and multiple sensing electrodes. For example, the driving electrode may be defined as a first sensing electrode, and the sensing electrode may be defined as a second sensing electrode. For another example, the driving electrode may be defined as a second sensing electrode, and the sensing electrode may be defined as a first sensing electrode.

The non-display area NDA may surround the display area DA. A gate driver GIC, fan-out lines FOL and gate control lines GCL may be disposed in the non-display area NDA. The gate driver GIC may generate multiple gate signals based on a gate control signal, and may sequentially supply multiple gate signals to multiple gate lines GL in accordance with a predetermined order.

The fan-out lines FOL may be extended from a pad area PA and touch pad areas TPA1 and TPA2 to the display area DA. The fan-out lines FOL may include first fan-out lines FOL1 and second fan-out lines FOL2.

The first fan-out lines FOL1 may be extended from the pad area PA to the display area DA via the driving chip IC. The first fan-out lines FOL1 may supply the data voltage received from the driving chip IC to multiple data lines DL. The second fan-out lines FOL2 may be extended from the touch pad area TPA to the display area DA. The second fan-out lines FOL2 may provide the touch driving signal provided from the touch driving chip TIC to the touch electrodes TEL.

The gate control line GCL may be extended from the driving chip IC to the gate driver GIC. The gate control line GCL may supply the gate control signal received from the driving chip IC to the gate driver GIC.

The protrusion of the non-display area NDA may include a driving chip IC, a pad area PA and touch pad areas TPA1 and TPA2.

The driving chip IC may output signals and voltages for driving the display panel 10 to the first fan-out lines FOL1. The driving chip IC may supply the data voltage to the data line DL through the first fan-out lines FOL. The data voltage may be supplied to multiple pixels PX, and may control luminance of multiple pixels PX. The driving chip IC may supply the gate control signal to the gate driver GIC through the gate control line GCL.

The pad area PA and the touch pad areas TPA1 and TPA2 may be disposed at the edge of the protrusion of the non-display area NDA. For example, the pad area PA and the touch pad areas TPA1 and TPA2 may be disposed to be adjacent to the other end of the protrusion of the non-display area NDA in the second direction DR2. The pad area PA and the touch pad areas TPA1 and TPA2 may be electrically connected to the printed circuit film FPCB through a bonding member.

The pad area PA may include multiple display pad portions DP. Multiple display pad portions DP may be electrically connected to a graphic system through the printed circuit film FPCB. Multiple display pad portions DP may be electrically connected to the printed circuit film FPCB to receive digital video data from the graphic system, and may supply the digital video data to the driving chip IC.

The touch pad areas TPA1 and TPA2 may include a first touch pad area TPA1 and a second touch pad area TPA2. The first touch pad area TPA1 may include multiple first touch pads TP1, and the second touch pad area TPA2 may include multiple second touch pads TP2.

Multiple first touch pads TP1 and multiple second touch pads TP2 may be electrically connected to the touch driving chip TIC through the printed circuit film FPCB. Multiple first touch pads TP1 and multiple second touch pads TP2 may be electrically connected to the printed circuit film FPCB to receive the touch driving signal from the touch driving chip TIC.

Multiple first touch pads TP1 and multiple second touch pads TP2 may provide the touch driving signal provided from the touch driving chip TIC to the touch electrodes TEL through the second fan-out lines FOL2. Multiple first touch pads TP1 and multiple second touch pads TP2 may provide a touch sensing signal sensed from the touch electrodes TEL to the touch driving chip TIC through the second fan-out lines FOL2.

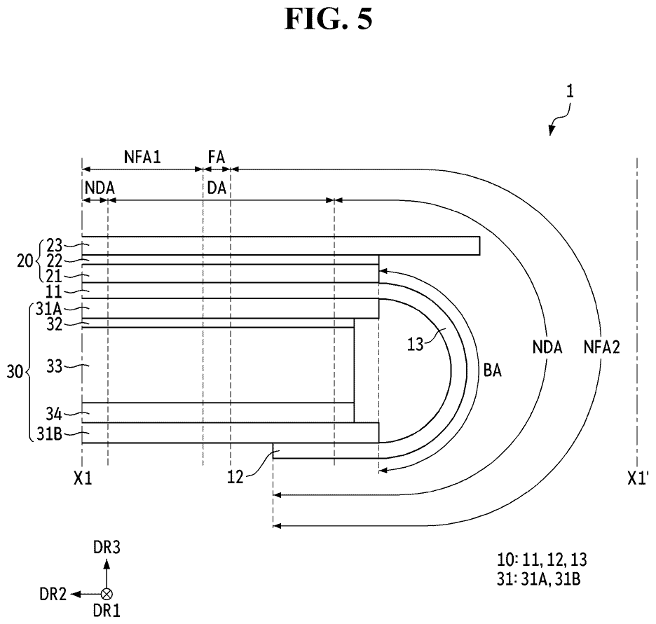

FIG. 5 is a schematic cross-sectional view illustrating a display device taken along line X1-X1′ of FIG. 1.

Referring to FIG. 5 in addition to FIGS. 2 and 3, the display device 1 may include a display panel 10, an upper stacked structure 20 and a lower stacked structure 30. The upper stacked structure 20 may include a panel upper member 21, a window member 22, and an upper protective member 23. The lower stacked structure 30 may include a panel support film 31, an adhesive layer 32, a lower functional member 33, and a cover spacer 34.

The display panel 10 may include a first portion 11, a second portion 12, and a third portion 13.

The first portion 11 may be disposed between the upper stacked structure 20 and the lower stacked structure 30. The first portion 11 may not overlap the bending area BA. The first portion 11 may be disposed at as of the bending area BA.

The second portion 12 may be disposed below the lower stacked structure 30. The second portion 12 may not overlap the bending area BA. The second portion 12 may be disposed at another side of the bending area BA. The second portion 12 may be a portion where the display panel 10 is bent and then positioned below the lower stacked structure 30.

The third portion 13 may be disposed between the first portion 11 and the second portion 12. The third portion 13 may be a portion disposed in the bending area BA of the display panel 10. The third portion 13 may be a portion where the display panel 10 is bent to have a curvature.

For convenience of description, although the first portion 11, the second portion 12 and the third portion 13 will be described separately, the first portion 11, the second portion 12 and the third portion 13 may be a physically integral element to constitute one display panel 10.

The upper stacked structure 20 may include a panel upper member 21, a window member 22, and an upper protective member 23.

The panel upper member 21 may be disposed on an entire surface of the display panel 10. For example, the panel upper member 21 may be disposed on the first portion 11 of the display panel 10.

The panel upper member 21 may be a protective member. The panel upper member 21 may perform an impact mitigating function for protecting the display panel 10 from an external impact (or force). The panel upper member 21 may include a material having high flexibility and high rigidity. For example, the panel upper member 21 may include a flexible plastic material such as polyimide (PI) and polyethylene terephthalate (PET).

In other embodiments, the panel upper member 21 may be an optical member. The panel upper member 21 may perform an anti-reflection function. The panel upper member 21 may reduce reflectance of external light incident from an upper side of the window member 22. The panel upper member 21 may include a phase retarder, a polarizer and a destructive interference structure. For example, the phase retarder and the polarizer may be film types or liquid crystal coating types. The destructive interference structure may include a first reflective layer and a second reflective layer, which are disposed on their respective layers different from each other. The first reflective light and the second reflective light, which are respectively reflected from the first reflective layer and the second reflective layer, may be subjected to destructive interference, whereby reflectance of external light may be reduced.

In case that the panel upper member 21 performs an impact mitigating function or an anti-reflection function, the panel upper member 21 may further include an adhesive layer below a functional layer for performing the impact mitigating function or the anti-reflection function. The adhesive layer may include a transparent adhesive such as a pressure sensitive adhesive (PSA), an optically clear adhesive (OCA), and an optically clear resin (OCR). The panel upper member 21 may be transported and processed by integrally combining the functional layer with the adhesive layer.

In other embodiments, the panel upper member 21 may be an adhesive member. The panel upper member 21 may perform an adhesive function. The panel upper member 21 may couple the window member 22 to the display panel 10. For example, the panel upper member 21 may include only an adhesive layer for performing an adhesive function, and may not include a functional layer for performing the impact mitigating function or the anti-reflection function. For example, the panel upper member 21 may be made of a transparent adhesive such as a pressure sensitive adhesive (PSA), an optically clear adhesive (OCA) and an optically clear resin (OCR).

The window member 22 may be attached onto an entire surface of the panel upper member 21. The window member 22 may be made of a transparent material, and may be, for example, glass or plastic. For example, the window member 22 may be an ultra-thin glass (UTG) having a thickness of 0.1 mm or less or a transparent polyimide film.

The upper protective member 23 may be disposed on an entire surface of the window member 22. The upper protective member 23 may perform at least one function of shock absorption, anti-scratch, anti-fingerprinting, anti-glare or anti-scattering of the window member 200. The upper protective member 23 may include a material that has high flexibility and is resistant to scratches. For example, the upper protective member 23 may be a polymer film or a reinforced glass film.

The lower stacked structure 30 may include a panel support film 31, an adhesive layer 32, a lower functional member 33, and a cover spacer 34.

The panel support film 31 may serve to support the display panel 10 and protect a rear surface of the display panel 10. The panel support film 31 may be made of plastic such as polyethylene terephthalate (PET) or polyimide.

The panel support film 31 may not be disposed in the bending area BA for smooth bending of the display panel 10 in the bending area BA. For example, the panel support film 31 may be disposed on the first portion 11 of the display panel 10 and the second portion 12 of the display panel 10, but may not be disposed on the third portion 13 of the display panel 10. The panel support film 31 may include a first panel support film 31A and a second panel support film 31B spaced apart from each other in the third direction DR3.

The first panel support film 31A may be disposed on a rear surface (e.g., a lower surface of the first portion 11 in the drawing) of the first portion 11 of the display panel 10. The first panel support film 31A may support the first portion 11 of the display panel 10 and protect the rear surface of the first portion 11 of the display panel 10.

The second panel support film 31B may be disposed on a rear surface (e.g., an upper surface of the second portion 12 in the drawing) of the display panel 10. The second panel support film 31B may support the second portion 12 of the display panel 10 and protect the rear surface of the second portion 12 of the display panel 10.

The lower functional member 33 may be disposed on a rear surface of the first panel support film 31A. The lower functional member 33 may include at least one of a support layer for adding rigidity to the display panel 10, a light shielding layer for absorbing light incident from the outside, a buffer layer for absorbing impact from the outside, or a heat dissipation layer for efficiently dissipating heat of the display panel 10.

The support layer may support the display panel 10. The support layer may be a rigid member of which shape or volume is not changed readily by external pressure. The support layer may be a polymer that includes a carbon fiber or a glass fiber. In case that the lower functional member 33 includes a digitizer, the support layer may be formed of a polymer that includes a carbon fiber or a glass fiber, to pass through a magnetic field or an electromagnetic signal of the digitizer.

In other embodiments, the support layer may be a metal plate. For example, the support layer is a metal plate, and may be made of a metal or a metal alloy. The support layer may include copper (Cu), aluminum (Al), stainless (SUS), and/or their alloy, but is not limited thereto.

The light shielding layer may shield transmission of light to prevent elements disposed therebelow from being visually recognized on the display panel 10. The light shielding layer may include a light absorbing material such as a black pigment or a black dye.

The buffer layer may absorb external impact to prevent the display panel 10 from being damaged. The buffer layer may be formed of a single layer or multiple layers. For example, the buffer layer may be formed of a polymer resin such as polyurethane, polycarbonate, polypropylene and polyethylene, or may include a material having elasticity such as rubber, a urethane-based material or a sponge formed by foaming an acrylic-based material.

The heat dissipation layer may include a first heat dissipation layer containing graphite or carbon nanotube, and a second heat dissipation layer formed of a metal thin film such as copper, nickel, ferrite, and silver, which are capable of shielding electromagnetic waves and have excellent thermal conductivity.

The adhesive layer 32 may be disposed on the rear surface of the first panel support film 31A. The adhesive layer 32 may be disposed between the first panel support film 31A and the lower functional member 33. The first panel support film 31A and the lower functional member 33 may be coupled to each other through the adhesive layer 32. The adhesive layer 32 may be made of a transparent adhesive such as a pressure sensitive adhesive (PSA), an optically clear adhesive (OCA) and an optically clear resin (OCR).

The cover spacer 34 may uniformly maintain a distance between the lower functional member 33 and the second portion 12 of the display panel 10 in the third direction DR3 in case that the display panel 10 is bent. The cover spacer 34 may control the degree of bending (or curve) of the display panel 10. The cover spacer 34 may support the second portion 12 of the display panel 10. The cover spacer 34 may include an organic insulating material, but is not limited thereto.

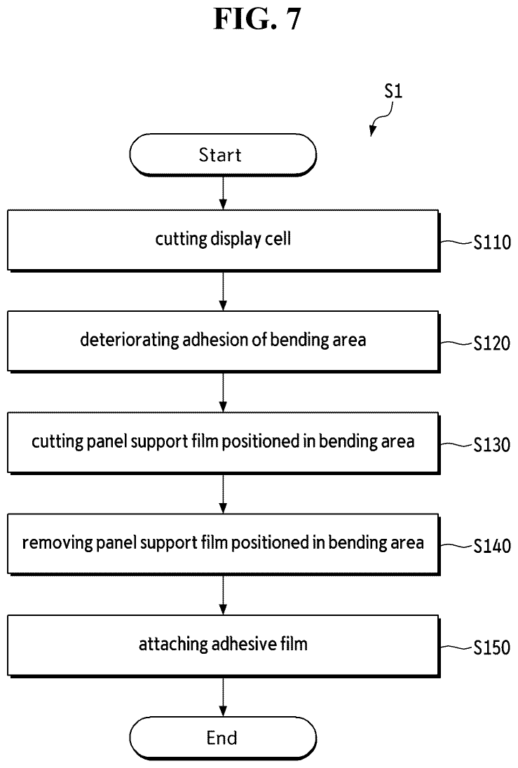

In case that the display device 1 according to the embodiment is manufactured, a process of disposing the panel support film 31 and the adhesive layer 32 on the rear surface of the display panel 10 may be performed through a continuous process. For example, a process of forming the panel support film 31 on the rear surface of the display panel 10 and forming the adhesive layer 32 on the panel support film 31 may be performed by a continuous process. The continuous process means that a second process is performed immediately after a first process without changing a subject or changing a position. This will be described together with a method for manufacturing a display device according to one embodiment with reference to FIG. 7 and the like.

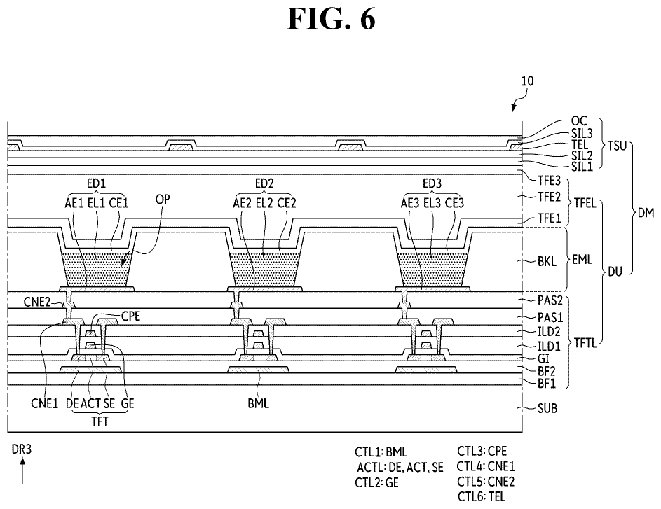

FIG. 6 is a schematic cross-sectional view illustrating a display panel according to one embodiment.

Referring to FIG. 6, the display panel 10 may include a substrate SUB and a display module DM disposed on the substrate SUB. The display module DM may include a display layer DU and a touch sensing layer TSU. The display layer DU may include a thin film transistor layer TFTL, a light emitting element layer EML, and a thin film encapsulation layer TFEL.

The substrate SUB may be a base substrate (or a base member). The substrate SUB may be a flexible substrate capable of being subjected to bending, folding, rolling and the like. For example, the substrate SUB may include a polymer resin such as polyimide (PI), but is not limited thereto. For another example, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The thin film transistor layer TFTL may include a first conductive layer CTL1, an active layer ACTL, a second conductive layer CTL2, a third conductive layer CTL3, a fourth conductive layer CTL4, and a fifth conductive layer CTL5.

The conductive layer is a layer having conductivity by including a conductive material, and layers formed of the conductive layers of the same name may be formed by the same process, or may include the same material. The insulating layers or the passivation layers, which are directly positioned on upper and lower portions of the same conductive layer, may be the same as each other. However, in case that the insulating layers or the passivation layers, which are directly positioned on upper and lower portions of the same conductive layer, are omitted in some areas, they may not be the same as each other.

The first buffer layer BF1 may be disposed on the substrate SUB. The first buffer layer BF1 may include an inorganic layer capable of preventing permeation of the air or moisture. For example, the first buffer layer BF1 may include multiple inorganic layers that are alternately stacked.

The first conductive layer CTL1 may be disposed on the first buffer layer BF1. The first conductive layer CTL1 may include a lower metal layer BML. The lower metal layer BML may include a material for shielding light, thereby preventing light from being incident on a semiconductor area ACT. For example, the lower metal layer BML may be formed of a single layer or a multi-layer, which is made of any one of molybdenum (Mo), aluminum (Al), chromium (Cr), gold (Au), titanium (Ti), nickel (Ni), neodymium (Nd) and copper (Cu), or their alloy. In other embodiments, the lower metal layer BML may be omitted.

The second buffer layer BF2 may be disposed on the first conductive layer CTL1. The second buffer layer BF2 may cover the first buffer layer BF1 and the lower metal layer BML. The second buffer layer BF2 may include an inorganic layer capable of preventing permeation of the air or moisture. For example, the second buffer layer BF2 may include multiple inorganic layers that are alternately stacked.

The thin film transistor TFT may be disposed on the second buffer layer BF2. The thin film transistor TFT may constitute a pixel circuit of each of multiple pixels. For example, the thin film transistor TFT may be a driving transistor or a switching transistor of the pixel circuit. The thin film transistor TFT may include a semiconductor area ACT, a source electrode SE, a drain electrode DE, and a gate electrode GE. However, the connection electrode CNE, which will be described later, may be also considered as an element included in the thin film transistor TFT.

The active layer ACTL may be disposed on the second buffer layer BF2. The active layer ACTL may include the semiconductor area ACT, the drain electrode DE, and the source electrode SE.

The semiconductor area ACT may overlap the lower metal layer BML and the gate electrode GE in the third direction (e.g., thickness direction). The semiconductor area ACT may be insulated from the gate electrode GE by the gate insulating layer GI. A material of the semiconductor area ACT may be conductorized to form the source electrode SE and the drain electrode DE in a portion of the semiconductor area ACT.

The gate insulating layer GI may be disposed on the active layer ACTL. The gate insulating layer GI may cover the semiconductor area ACT and the second buffer layer BF2. The gate insulating layer GI may insulate the semiconductor area ACT from the gate electrode GE. The gate insulating layer GI may include a contact hole through which the first connection electrode CNE1 passes.

The second conductive layer CTL2 may be disposed on the gate insulating layer GI. The second conductive layer CTL2 may include a gate electrode GE. The gate electrode GE may overlap the semiconductor area ACT with the gate insulating layer GI interposed therebetween.

The first interlayer insulating layer ILD1 may be disposed on the second conductive layer CTL2. The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be electrically connected to the contact hole of the gate insulating layer GI and a contact hole of the second interlayer insulating layer ILD2.

The third conductive layer CTL3 may be disposed on the first interlayer insulating layer ILD1. The third conductive layer CTL3 may include a capacitor electrode CPE. The capacitor electrode CPE may overlap the gate electrode GE in the third direction DR3 (e.g., thickness direction). The capacitor electrode CPE and the gate electrode GE may form capacitance.

The second interlayer insulating layer ILD2 may be disposed on the third conductive layer CTL3. The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be electrically connected to the contact hole of the first interlayer insulating layer ILD1 and the contact hole of the gate insulating layer GI.

The fourth conductive layer CTL4 may be disposed on the second interlayer insulating layer ILD2. The fourth conductive layer CTL4 may include a first connection electrode CNE1. The first connection electrode CNE1 may electrically connect the source electrode SE or the drain electrode DE of the thin film transistor TFT to the second connection electrode CNE2. The first connection electrode CNE1 may be inserted into the contact holes formed in the second interlayer insulating layer ILD2, the first interlayer insulating layer ILD1 and the gate insulating layer GI to contact the source electrode SE or the drain electrode DE of the thin film transistor TFT. As described above, the first connection electrode CNE1 may be also considered as an element included in the thin film transistor TFT. The first connection electrode CNE1 may perform the same function as the source electrode SE or the drain electrode DE of the thin film transistor TFT.

The first passivation layer PAS1 may be disposed on the fourth conductive layer CTL4. The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The fifth conductive layer CTL5 may be disposed on the first passivation layer PAS1. The fifth conductive layer CTL5 may include a second connection electrode CNE2. The second connection electrode CNE2 may electrically connect the first connection electrode CNE1 to pixel electrodes AE1, AE2, and AE3 of light emitting elements ED1, ED2, and ED3. The second connection electrode CNE2 may be inserted into the contact hole formed in the first passivation layer PAS1 to contact the first connection electrode CNE1. As described above, the second connection electrode CNE2 may be also considered as an element included in the thin film transistor TFT. The second connection electrode CNE2 may perform the same function as the source electrode SE or the drain electrode DE of the thin film transistor TFT.

The second passivation layer PAS2 may be disposed on the fifth conductive layer CTL5. The second passivation layer PAS2 may cover the second connection electrode CNE2 and the first passivation layer PAS1. The second passivation layer PAS2 may include a contact hole through which the pixel electrodes AE1, AE2, and AE3 of the light emitting elements ED1, ED2, and ED3 pass.

The light emitting element layer EML may be disposed on the thin film transistor layer TFTL. The light emitting element layer EML may include light emitting elements ED1, ED2, and ED3 and a bank layer BKL. The light emitting elements ED1, ED2, and ED3 may include pixel electrodes AE1, AE2, and AE3, light emitting layers EL1, EL2, and EL3, and common electrodes CE1, CE2, and CE3.

The pixel electrodes AE1, AE2, and AE3 may be disposed on the second passivation layer PAS2. The pixel electrodes AE1, AE2, and AE3 may be disposed to overlap any one of openings OP of the bank layer BKL. The pixel electrodes AE1, AE2, and AE3 may be electrically connected to the source electrode SE or the drain electrode DE of the thin film transistor TFT through the first and second connection electrodes CNE1 and CNE2.

The pixel electrodes AE1, AE2, and AE3 may include a first pixel electrode AE1, a second pixel electrode AE2, and a third pixel electrode AE3, which are disposed in each pixel PX. The first pixel electrode AE1, the second pixel electrode AE2, and the third pixel electrode AE3 may be spaced apart from one another on the second passivation layer PAS2 in a direction intersecting the third direction DR3. In other embodiments, the pixel electrodes AE1, AE2, and AE3 may respectively constitute the light emitting elements ED1, ED2, and ED3 for emitting light of different colors.

The light emitting layers EL1, EL2, and EL3 may be disposed on the pixel electrodes AE1, AE2, and AE3.

The light emitting layers EL1, EL2, and EL3 may be organic light emitting layers made of organic materials. In the light emitting layers EL1, EL2, and EL3, in case that the thin film transistor TFT applies a predetermined voltage to the pixel electrodes AE1, AE2, and AE3 of the light emitting elements ED1, ED2, and ED3, and the common electrodes CE1, CE2, and CE3 of the light emitting elements ED1, ED2, and ED3 receive a common voltage or a cathode voltage, holes and electrons may move to the light emitting layers EL1, EL2, and EL3 through a hole transport layer and an electron transport layer, respectively, and may be combined with each other in the light emitting layers EL1, EL2, and EL3 to emit light.

In other embodiments, the light emitting elements ED1, ED2, and ED3 may include a quantum dot light emitting diode including a quantum dot light emitting layer, an inorganic light emitting diode including an inorganic semiconductor, or a micro light emitting diode.

The light emitting layers EL1, EL2, and EL3 may include a first light emitting layer EL1, a second light emitting layer EL2, and a third light emitting layer EL3. The first light emitting layer EL1 may be disposed on the first pixel electrode AE1, the second light emitting layer EL2 may be disposed on the second pixel electrode AE2, and the third light emitting layer EL3 may be disposed on the third pixel electrode AE3. The first to third light emitting layers EL1, EL2, and EL3 may be light emitting layers of the first to third light emitting elements ED1, ED2, and ED3, respectively.

In other embodiments, the first light emitting layer EL1 may be a light emitting layer for emitting red light of a first color, the second light emitting layer EL2 may be a light emitting layer for emitting green light of a second color, and the third light emitting layer EL3 may be a light emitting layer for emitting blue light of a third color, but the disclosure is not limited thereto.

The common electrodes CE1, CE2, and CE3 may be disposed on the light emitting layers EL1, EL2, and EL3. The common electrodes CE1, CE2, and CE3 may include a transparent conductive material so that light generated from the light emitting layers EL1, EL2, and EL3 may be transmitted therethrough. The common electrodes CE1, CE2, and CE3 may receive a common voltage or a low potential voltage. In case that the pixel electrodes AE1, AE2, and AE3 receive a voltage corresponding to the data voltage and the common electrodes CE1, CE2, and CE3 receive a low potential voltage, a potential difference is formed between the pixel electrodes AE1, AE2, and AE3 and the common electrodes CE1, CE2, and CE3 so that the light emitting layers EL1, EL2, and EL3 may emit light.

The common electrodes CE1, CE2, and CE3 may include a first common electrode CE1, a second common electrode CE2, and a third common electrode CE3. The first common electrode CE1 may be disposed on the first light emitting layer EL1, the second common electrode CE2 may be disposed on the second light emitting layer EL2, and the third common electrode CE3 may be disposed on the third light emitting layer EL3. However, as shown in the drawings, the common electrodes CE1, CE2, and CE3 may overlap multiple pixels PX as integrated electrodes, and may be disposed over an entire surface of the display layer DU along sides and an upper surface of the bank layer BKL and upper surfaces of the light emitting layers EL1, EL2, and EL3.

The bank layer BKL may be disposed on the thin film transistor layer TFTL or the substrate SUB. The bank layer BKL may include an opening OP disposed in each pixel PX. The opening OP of the bank layer BKL may partition light emission areas of the light emitting elements ED1, ED2, and ED3. For example, the light emitting elements ED1, ED2, and ED3 may overlap the openings OP of the bank layer BKL in the third direction DR3 (e.g., thickness direction), respectively.

In other embodiments, the openings OP of the bank layer BKL may overlap the pixel electrodes AE1, AE2, and AE3 in the third direction DR3 (e.g., thickness direction), and may expose portions of the pixel electrodes AE1, AE2, and AE3 therebelow. For example, the bank layer BKL may cover portions of the pixel electrodes AE1, AE2, and AE3 on both ends of the pixel electrodes AE1, AE2, and AE3, and may expose the remaining portions through the openings OP.

In other embodiments, the light emitting layers EL1, EL2, and EL3 of the light emitting elements ED1, ED2, and ED3 may be disposed in the openings OP of the bank layer BKL, but are not limited thereto. The light emitting layers EL1, EL2, and EL3 may be disposed to be conformal on the bank layer BKL along the sides and the upper surface of the bank layer BKL.

In other embodiments, the common electrodes CE1, CE2, and CE3 may be disposed to be conformal on the bank layer BKL along the sides and the upper surface of the bank layer BKL, but are not limited thereto. The common electrodes CE1, CE2, and CE3 may be disposed in the openings OP of the bank layer BKL.

The thin film encapsulation layer TFEL may be disposed on the light emitting elements ED1, ED2, and ED3 and the bank layer BKL, and may cover multiple light emitting elements ED1, ED2, and ED3 and the bank layer BKL. The thin film encapsulation layer TFEL may include at least one inorganic layer to prevent oxygen or moisture from being permeated into the light emitting element layer EML. The thin film encapsulation layer TFEL may include at least one organic layer to protect the light emitting element layer EML from particles such as dust.

The thin film encapsulation layer TFEL may include a first encapsulation layer TFE1, a second encapsulation layer TFE2 and a third encapsulation layer TFE3, which are sequentially stacked in the third direction DR3 (e.g., thickness direction). The first encapsulation layer TFE1 and the third encapsulation layer TFE3 may be inorganic encapsulation layers, and the second encapsulation layer TFE2 disposed therebetween may be an organic encapsulation layer.

Each of the first encapsulation layer TFE1 and the third encapsulation layer TFE3 may include at least one inorganic insulating material. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. The polymer-based material may include an acrylic resin, an epoxy resin, polyimide, polyethylene, and the like. For example, the second encapsulation layer TFE2 may include an acrylic resin, for example, polymethyl methacrylate, polyacrylic acid, and the like. The second encapsulation layer TFE2 may be formed by curing a monomer or coating a polymer.

The first encapsulation layer TFE1 may be disposed on each of the common electrodes CE1, CE2, and CE3. The first encapsulation layer TFE1 may be disposed to be conformal along a shape of the common electrodes CE1, CE2, and CE3. The second encapsulation layer TFE2 may be disposed on the first encapsulation layer TFE1. The second encapsulation layer TFE2 may serve to planarize a step difference of a lower layer. The third encapsulation layer TFE3 may be disposed on the second encapsulation layer TFE2.

The touch sensing layer TSU may be disposed on the thin film encapsulation layer TFEL. The touch sensing layer TSU may include a first touch insulating layer SIL1, a second touch insulating layer SIL2, a touch electrode TEL, a third touch insulating layer SIL3, and an overcoat layer OC. The touch sensing layer TSU may include a sixth conductive layer CTL6.

The first touch insulating layer SIL1 may be disposed on the thin film encapsulation layer TFEL. The first touch insulating layer SIL1 may have insulating and optical functions. The first touch insulating layer SIL1 may include at least one inorganic layer. Optionally, the first touch insulating layer SIL1 may be omitted.

The second touch insulating layer SIL2 may cover the first touch insulating layer SIL1. In other embodiments, a touch electrode of another layer in addition to the touch electrode TEL disposed on the second touch insulating layer SIL2 may be further disposed on the first touch insulating layer SIL1. For example, the second touch insulating layer SIL2 may cover the touch electrode of another layer. The second touch insulating layer SIL2 may have insulating and optical functions. For example, the second touch insulating layer SIL2 may be an inorganic layer that includes at least one of a silicon nitride layer, a silicon oxynitride layer, a silicon oxide layer, a titanium oxide layer or an aluminum oxide layer.

The sixth conductive layer CTL6 may be disposed on the second touch insulating layer SIL2. The sixth conductive layer CTL6 may include a touch electrode TEL. The touch electrode TEL may not overlap the light emitting elements ED1, ED2, and ED3 in the third direction DR3 (e.g., thickness direction). The touch electrode TEL may be formed of a single layer of molybdenum (Mo), titanium (Ti), copper (Cu), aluminum (Al) or indium tin oxide (ITO), or may be formed of a stacked structure (Ti/Al/Ti) of aluminum and titanium, a stacked structure (ITO/AI/ITO) of aluminum and ITO, an APC alloy, or a stacked structure (ITO/APC/ITO) of an APC alloy and ITO.

The third touch insulating layer SIL3 may be disposed on the touch electrode TEL. The third touch insulating layer SIL3 may cover the touch electrode TEL and the second touch insulating layer SIL2. The third touch insulating layer SL3 may have insulating and optical functions. The third touch insulating layer SIL3 may be made of the material exemplified in the second touch insulating layer SIL2.

The overcoat layer OC may be disposed on the third touch insulating layer SIL3. The overcoat layer OC may planarize an upper end of the third touch insulating layer SIL3 that includes a step difference by the touch electrode TEL. The overcoat layer OC may be a colorless light-transmissive layer that does not have a color of a visible light band. For example, the overcoat layer OC may include a colorless light-transmissive organic material such as an acrylic resin.

A method for manufacturing a display device according to one embodiment will be described.

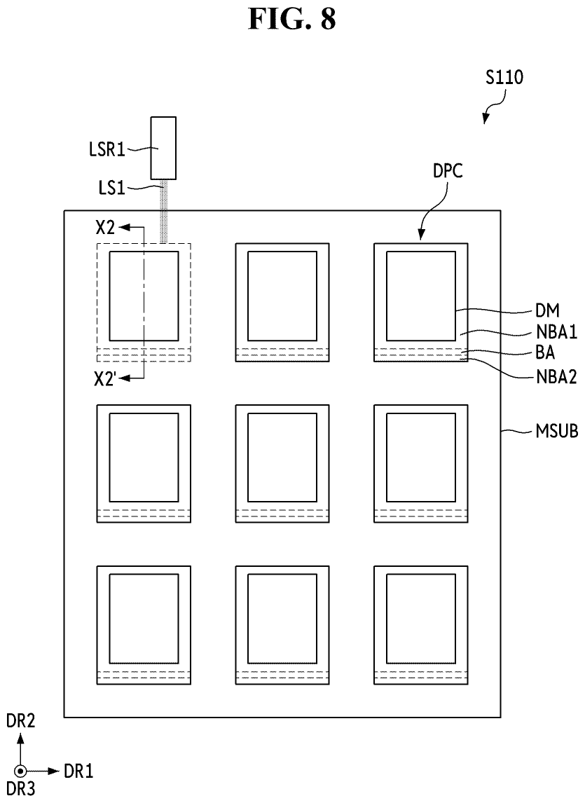

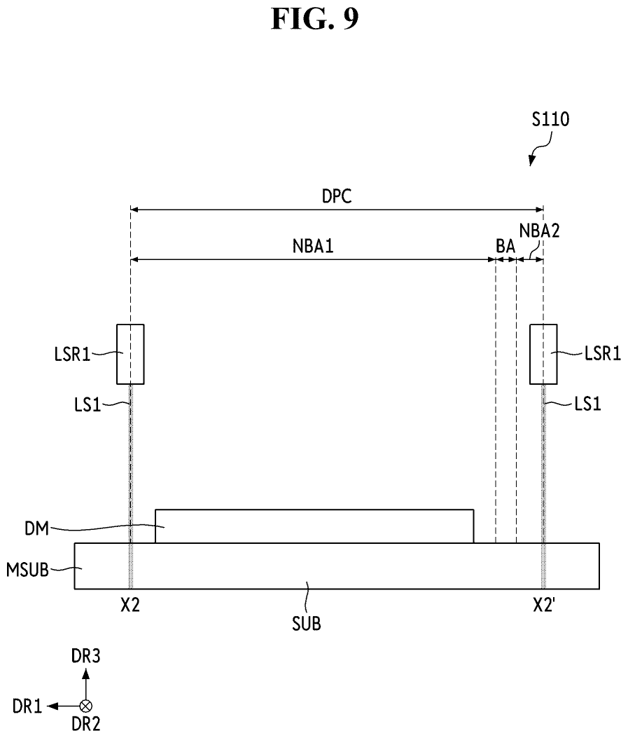

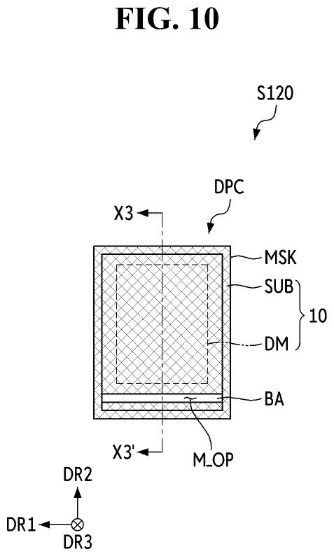

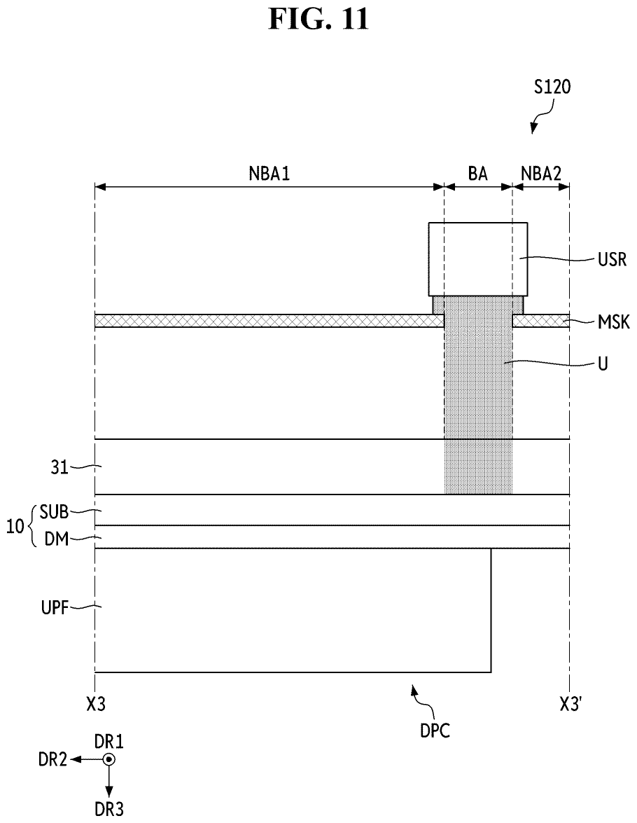

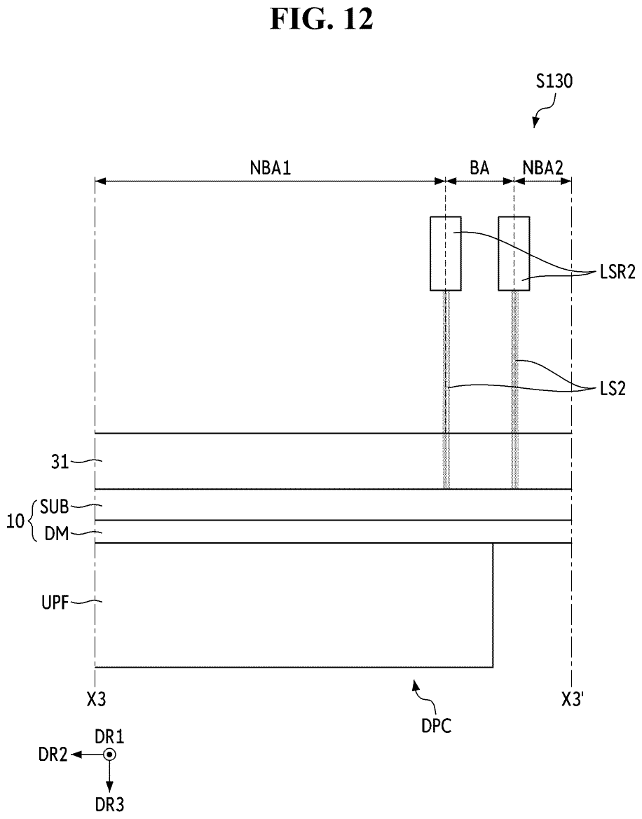

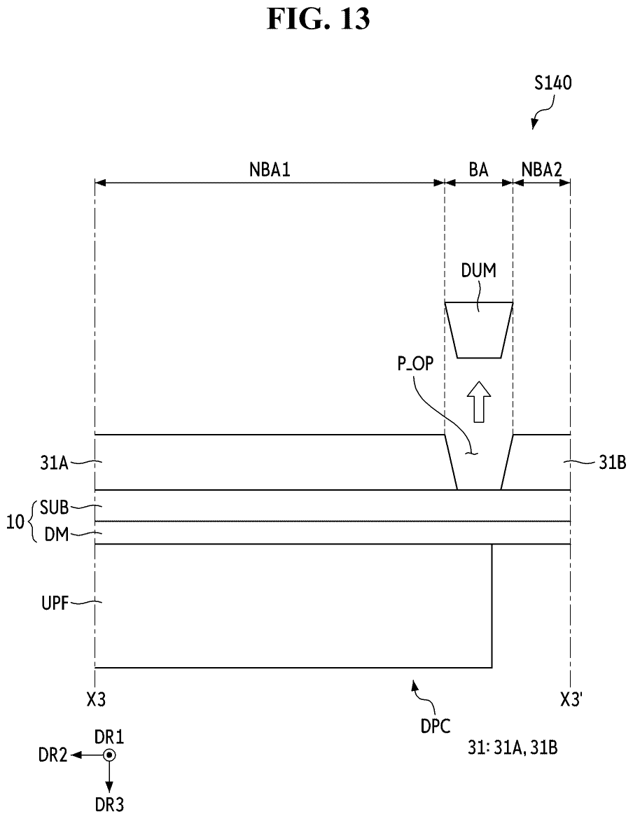

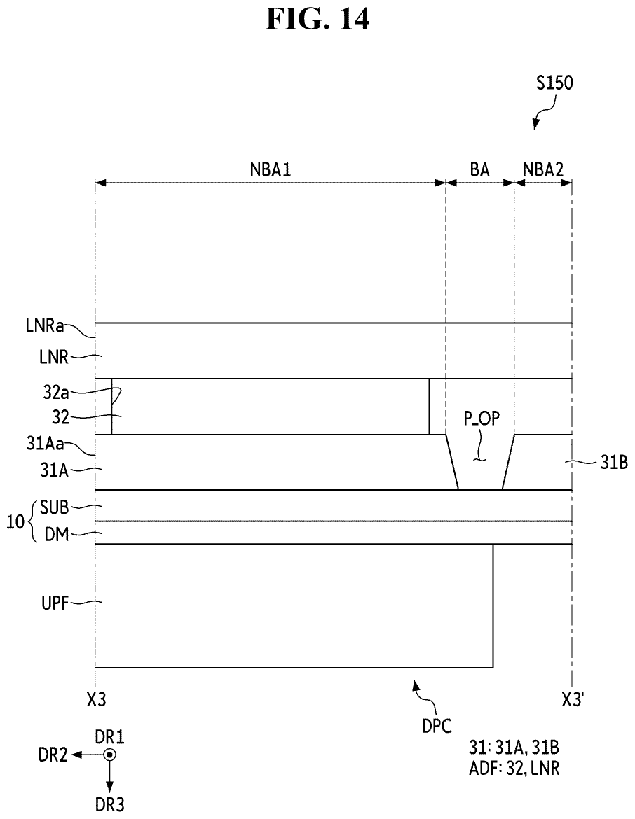

FIG. 7 is a schematic flow chart illustrating a method for manufacturing a display device, according to one embodiment. FIG. 8 is a schematic plan view illustrating step S110 of FIG. 7. FIG. 9 is a schematic cross-sectional view taken along line X2-X2′ of FIG. 8 to illustrate step S110 of FIG. 7. FIG. 10 is a schematic plan view illustrating step S120 in FIG. 7. FIG. 11 is a schematic cross-sectional view taken along line X3-X3′ of FIG. 10 to illustrate step S120 of FIG. 7. FIG. 12 is a schematic cross-sectional view taken along line X3-X3′ of FIG. 10 to illustrate step S130 of FIG. 7. FIG. 13 is a schematic cross-sectional view taken along line X3-X3′ of FIG. 10 to illustrate step S140 of FIG. 7. FIG. 14 is a schematic cross-sectional view taken along line X3-X3′ of FIG. 10 to illustrate step S150 of FIG. 7.

Referring to FIGS. 7 to 14, a method S1 for manufacturing a display device according to one embodiment may include a step S110 of cutting a display cell, a step S120 of deteriorating adhesion of a bending area, a step S130 of cutting a panel support film positioned in the bending area, a step S140 of removing the panel support film positioned in the bending area, and a step S150 of attaching an adhesive film.

As shown in FIGS. 8 and 9, in the step S110 of the cutting the display cell, multiple display cells DPC may be provided. The display cells DPC may be spaced apart from each other in the first direction DR1 and the second direction DR2. The display cells DPC may include a mother substrate MSUB and a display module DM disposed on the mother substrate MSUB. The display cells DPC may share the mother substrate MSUB in common, and each of the display cells DPC may include a display module DM.

Each of the display cells DPC may include a bending area BA, and a first non-bending area NBA1, and a second non-bending area NBA2, which are disposed on both sides of the bending area BA, respectively. The bending area BA may be substantially the same as the bending area BA of the display device 1 described above. The first non-bending area NBA1 may be disposed on a side of the bending area BA in the second direction DR2, and the second non-bending area NBA2 may be disposed on another side of the bending area BA in the second direction DR2.

In the step S110 of the cutting the display cell, a first cutting device LSR1 may cut and separate each display cell DPC from the mother substrate MSUB along the edges of the display cells DPC.

As the first cutting device LSR1, a scribe cutting device (scriber), a water-jet cutting device, an ultrasonic cutter, a plasma cutting device, a laser ablation device or the like may be applied. For example, in case that the first cutting device LSR1 is a laser ablation device, the first cutting device LSR1 may irradiate a first laser LS1 onto the mother substrate MSUB along the edge of the display cell DPC.

As shown in FIGS. 10 and 11, in the step S120 of the deteriorating the adhesion of the bending area, the display cell DPC cut and separated from the mother substrate MSUB by the first cutting device LSR1 may include a display panel 10. The display panel 10 of the display cell DPC may include a substrate SUB and a display module DM disposed on the substrate SUB. The display panel 10 of the display cell DPC may be substantially the same as the display panel 10 of the display device 1 according to the above-described embodiment.

The panel support film 31 may be attached onto the rear surface (the upper surface of the display panel 10 in FIG. 11) of the display panel 10. The panel support film 31 may be disposed on the entire surface over the bending area BA and the non-bending areas NBA1 and NBA2. Although not shown in the drawings, a separate adhesive element may be included between the display panel 10 and the panel support film 31. The adhesive element may include a transparent adhesive such as a pressure sensitive adhesive (PSA), an optically clear adhesive (OCA) and an optically clear resin (OCR), but is not limited thereto.

The upper protective film UPF may be attached onto the entire surface (the lower surface of the display panel 10 in FIG. 11) of the display panel 10. The upper protective film UPF may prevent components of the display module DM from being damaged in a process of manufacturing the display device 1. For example, the upper protective film UPF may include at least one of polyethylene terephthalate (PET), polypropylene (PP), polycarbonate (PC), polyethylene (PE) or polyvinyl chloride (PVC), but is not limited thereto.

In the step S120 of the deteriorating the adhesion of the bending area, an energy irradiation device USR may irradiate an energy source U to the interface between the display panel 10 and the panel support film 31 in the bending area BA or the adhesive element disposed on the interface.

In other embodiments, a mask MSK including a mask opening M_OP may be positioned on the rear surface of the panel support film 31. The energy source U of the energy irradiation device USR may be irradiated to the interface or the adhesive element through the mask opening M_OP. Therefore, physical properties of the interface or the adhesive element may be changed and thus adhesion of the adhesive element may be deteriorated.

The energy irradiation device USR may be a plasma processing device. For example, the energy source U may be plasma. In other embodiments, the energy irradiation device USR may be an ultraviolet irradiation device. For example, the energy source U may be ultraviolet rays.

As shown in FIG. 12, in the step S130 of the cutting the panel support film positioned in the bending area, a second cutting device LSR2 may cut the panel support film 31 at a boundary between the first non-bending area NBA1 and the bending area BA and a boundary between the second non-bending area NBA2 and the bending area BA.

As the second cutting device LSR2, a scribe cutting device (scriber), a water-jet cutting device, an ultrasonic cutter, a plasma cutting device, a laser ablation device or the like may be applied. For example, in case that the second cutting device LSR2 is a laser ablation device, the second cutting device LSR2 may irradiate a second laser LS2 to the panel support film 31 at the boundary between the first non-bending area NBA1 and the bending area BA and the boundary between the second non-bending area NBA2 and the bending area BA.

In other embodiments, the first laser LS1 irradiated by the first cutting device LSR1 and the second laser LS2 irradiated by the second cutting device LSR2 may have different magnitudes of energy. For example, since the first laser LS1 cuts the mother substrate MSUB and the second laser LS2 cuts the panel support film 31, the first laser LS1 and the second laser LS2 may be different from each other in energy magnitude. Furthermore, the first laser LS1 and the second laser LS2 may be also different from each other in a transmissive depth and a repetition rate.

As shown in FIG. 13, in the step S140 of the removing the panel support film positioned in the bending area, the adhesion of the adhesive element may be weakened on the interface between the display panel 10 to which the energy source U is irradiated and the panel support film 31 so that a dummy DUM portion of the panel support film 31 cut by the second cutting device LSR2 may be readily separated and removed from the display cell DPC.

An opening P_OP of the panel support film 31 may be formed at a position from the dummy DUM which is removed. The opening P_OP of the panel support film 31 may be disposed in the bending area BA. As the opening P_OP of the panel support film 31 is formed, bending stress may be minimized during bending of the display device 1.

The first panel support film 31A of the panel support film 31 may be disposed on a side of the opening P_OP of the panel support film 31, and the second panel support film 31B of the panel support film 31 may be disposed on another side thereof. The first panel support film 31A may be positioned in the first non-bending area NBA1, and the second panel support film 31B may be positioned in the second non-bending area NBA2.

In other embodiments, as shown in the drawing, a side portion of the dummy DUM and a side portion of the opening P_OP of the panel support film 310 may be inclined surfaces. For example, the second laser LS2 of the second cutting device LSR2 may be refracted in a moving direction by a refractive index of the panel support film 31 so that the side portion of the dummy DUM and the side portion of the opening P_OP of the panel support film 310 may be formed as inclined surfaces.

As shown in FIG. 14, in the step S150 of the attaching the adhesive film, an adhesive film ADF may be attached to the display cell DPC. The adhesive film ADF may be attached onto the rear surface (e.g., the upper surface in the drawing) of the panel support film 31.

The adhesive film ADF may include an adhesive layer 32 and a liner LNR.

The adhesive layer 32 may be disposed on the first panel support film 31A of the panel support film 31. The adhesive layer 32 may be positioned in the first non-bending area NBA1. The adhesive layer 32 may not be disposed in the bending area BA and the second non-bending area NBA2.

The liner LNR may be disposed on the adhesive layer 32. The liner LNR may be disposed over the first non-bending area NBA1, the bending area BA and the second non-bending area NBA2.

An end 32a of the adhesive layer 32 may be positioned more inward than an end LNRa of the liner LNR and an end 31Aa of the first panel support film 31A of the panel support film 31 in consideration of an adhesion tolerance of the adhesive film ADF. Therefore, the adhesive layer 32 may be exposed to the outside to prevent particles from being adhered to the adhesive layer 32.

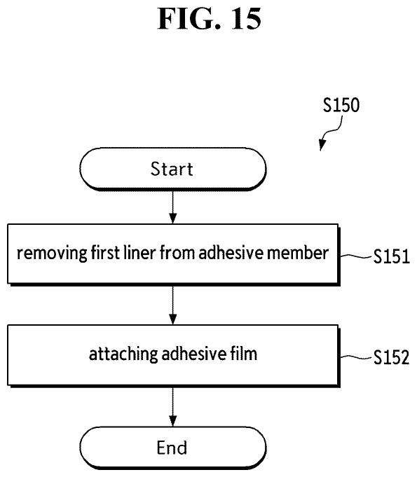

The step S150 will be described with reference to FIGS. 15 to 18.

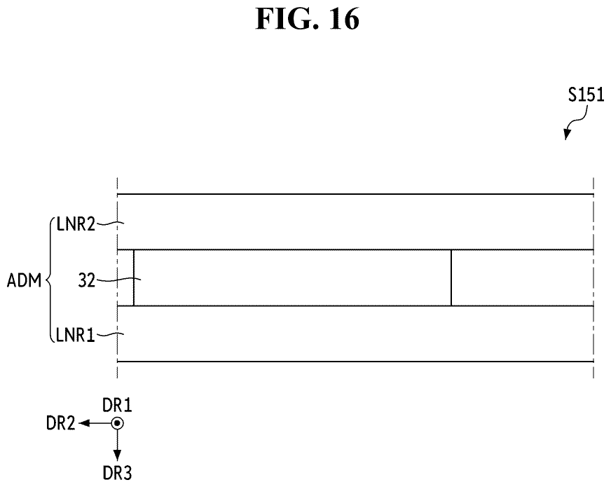

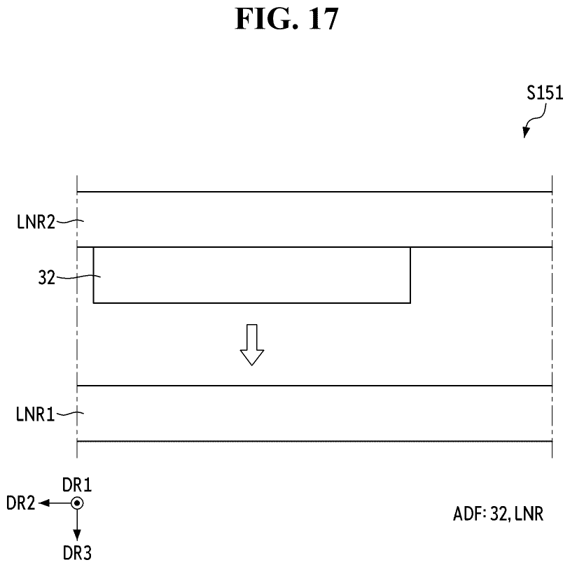

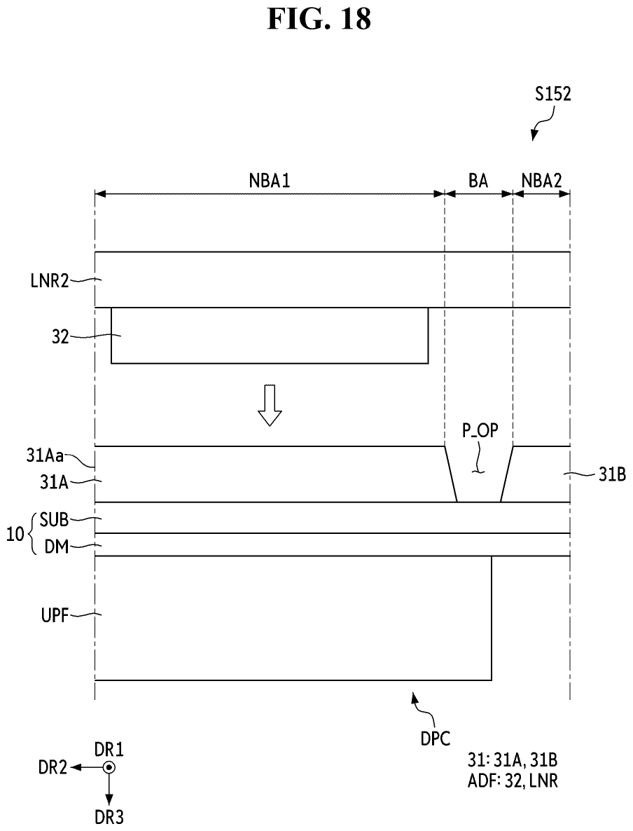

FIG. 15 is a schematic flow chart illustrating step S150 of FIG. 7. FIGS. 16 and 17 are schematic cross-sectional views illustrating step S151 of FIG. 15. FIG. 18 is a schematic cross-sectional view illustrating step S152 of FIG. 15.

Referring to FIGS. 15 to 18 in addition to FIG. 14, the step S150 of the attaching the adhesive film may include a step S151 of the removing the first liner from the adhesive member and a step S152 of the attaching the adhesive film.

As shown in FIGS. 16 and 17, in the step S151 of the removing the first liner, the adhesive member ADM may include a first liner LNR1, an adhesive layer 32, and a second liner LNR2.

The first liner LNR1 and the second liner LNR2 may be disposed on a surface and another surface of the adhesive layer 32, respectively. The adhesion between the first liner LNR1 and the adhesive layer 32 may be weaker than the adhesion between the second liner LNR2 and the adhesive layer 32. The first liner LNR1 may be removed before the adhesive film ADF is attached to the display cell DPC.

As shown in FIG. 18, in the step S152 of the attaching the adhesive film, the adhesive film ADF may be attached to the display cell DPC in a state that the first liner LNR1 is removed. For example, the second liner LNR2 may not be removed from the adhesive layer 32 but be attached to the display cell DPC together with the adhesive layer 32. Afterwards, while the display cell DPC is being stored, transported and processed for a subsequent process of the display cell DPC, the second liner LNR2 may be handled together with the display cell DPC in a state that it is attached to the display cell DPC.

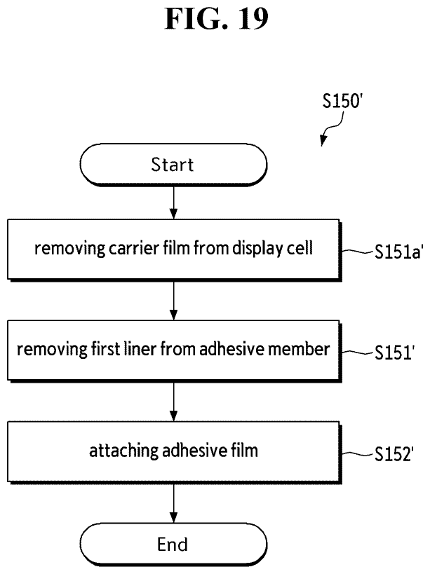

In the method S1 for manufacturing a display device according to the embodiment, the second liner LNR2 may be stored, transported and processed in a state that it is attached to the display cell DPC together with the adhesive layer 32 without being removed. For example, the display cell DPC may be handled in a state that the second liner LNR2 is attached thereto, whereby particles may be prevented from being permeated into the display panel 10. Since the liner LNR of the adhesive member ADM is used without attaching a separate carrier film, material cost may be reduced and process efficiency may be improved. This will be described later with reference to FIGS. 19 to 22.

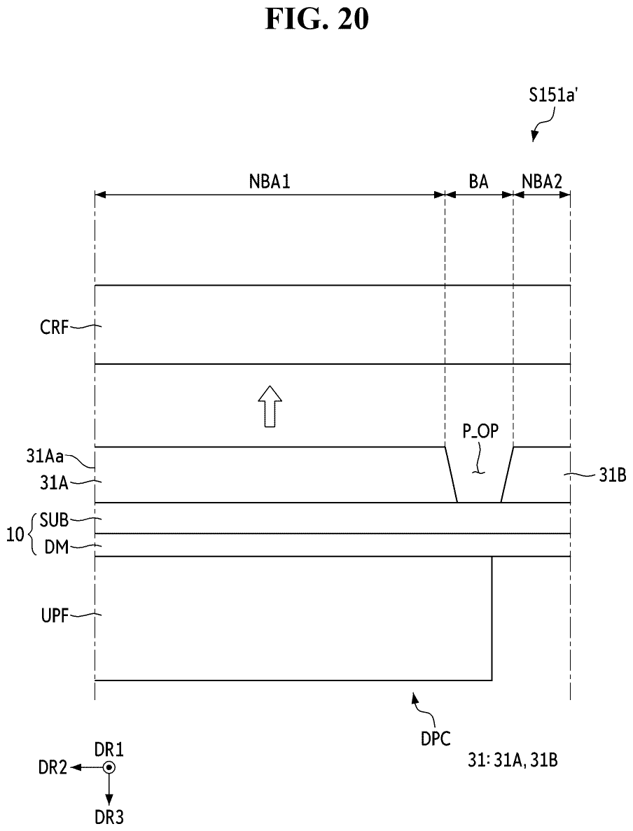

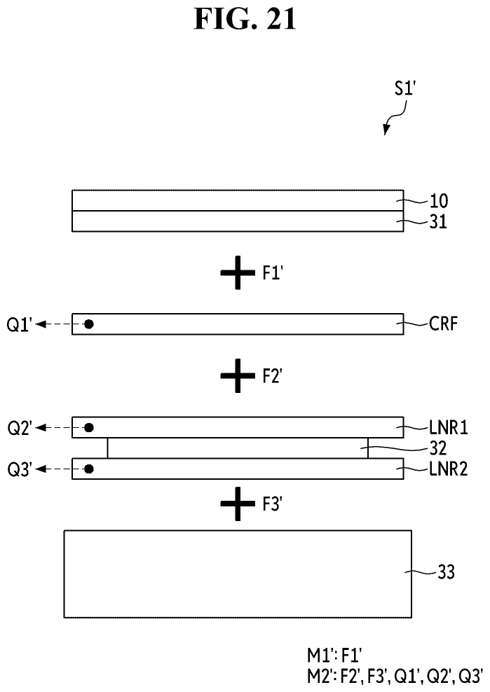

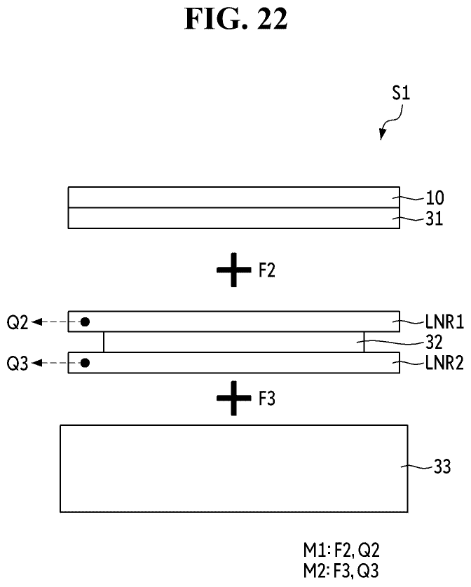

FIG. 19 is a schematic flow chart illustrating step S150′ of a method for manufacturing a display device according to a comparative embodiment. FIG. 20 is a schematic cross-sectional view illustrating step S151a′ of a method for manufacturing a display device according to a comparative embodiment. FIG. 21 is a schematic view illustrating a method for manufacturing a display device according to a comparative embodiment. FIG. 22 is a schematic view illustrating a method for manufacturing a display device according to one embodiment.

Referring to FIGS. 19 to 22 in addition to FIGS. 6 to 18, step S150′ of attaching an adhesive film in a method S1′ for manufacturing a display device according to the comparative example may include step S151a′ of removing a carrier film from a display cell, step of S151′ of removing a first liner from an adhesive member, and step of S152′ of attaching an adhesive film.

For example, as shown in FIG. 20, in the method S1′ for manufacturing a display device according to the comparative embodiment, a carrier film CRF may be attached to the display cell DPC before the adhesive film ADF is attached. The carrier film CRF may prevent particles from being permeated during a manufacturing process of the display device 1 and protect the display device 1, which is being manufactured, from external stress. In the method S1′ for manufacturing a display device according to the comparative embodiment, the adhesive film ADF may be attached after the carrier film CRF is removed.

As shown in FIG. 21, the method S1′ for manufacturing a display device according to the comparative embodiment may include a first coupling step F1′, a second coupling step F2′, a third coupling step F3′, a first removing step Q1′, a second removing step Q2′, and a third removing step Q3′.

The first coupling step F1′ may be included in a first process M1′, and the second coupling step F2, the third coupling step F3′, the first removing step Q1′, the second removing step Q2′, and the third removing step Q3′ may be included in a second process M2′. The first process M1′ may be a FAB (fabrication facility) process, and the second process M2′ may be a MOD (Module) process.

The FAB process is a panel manufacturing process of the display panel 10, and refers to a process of forming a display module DM on the substrate SUB. The MOD process refers to a process of bonding other modules disposed above and below the display panel 10. The FAB process may be performed through a continuous process in a clean room, and the MOD process may be performed in a space separate from the clean room. In other embodiments, behavior subjects of the FAB process and the MOD process may be different from each other, but are not limited thereto.

In the method S1′ for the manufacturing the display device according to the comparative embodiment, the display panel 10 and the panel support film 31 may be formed in the FAB process that is the first process M1′, and the adhesive layer 32 and the lower functional member 33 may be formed in the MOD process that is the second process M2′.

For example, in the method S1′ for the manufacturing the display device according to the comparative example since the process of attaching the adhesive layer 32 is performed in the second process M2′ that is the MOD process, the carrier film CRF may be attached in the first process M1′, which is the FAB process, to prevent the display panel 10 and the panel support film 31 from being contaminated and damaged. For example, the carrier film CRF may be attached to one surface of the panel support film 31 attached to the display panel 10 in the first coupling step F1′ of the method S1′ for the manufacturing the display device according to the comparative example.

The display panel 10 and the panel support film 31 may be kept with the carrier film CRF attached thereto between the first process M1′ and the second process M2′. Afterwards, the display panel 10 and the panel support film 31, to which the carrier film CRF is bonded, may be transported to a space for performing the second process M2′.

In the first removing step Q1′ of the second process M2′ of the method S1′ for manufacturing a display device according to the comparative embodiment, the carrier film CRF is removed. In the second removing step Q2′ of the second process M2′, the first liner LNR1 is removed. In the second coupling step F2′ of the second process M2′, the second liner LNR2 and the adhesive layer 32 are bonded to the display panel 10 and the panel support film 31. In the third removing step Q3′ of the second process M2′, the second liner LNR2 is removed. In the third coupling step F3′ of the second process M2′, the lower functional member 33 is coupled to the display panel 10 and the panel support film 31 by the adhesive layer 32.

On the other hand, as shown in FIG. 22, the method S1 for manufacturing a display device according to the embodiment may include a second coupling step F2, a third coupling step F3, a second removing step Q2, and a third removing step Q3.

The second coupling step F2 and the second removing step Q2 may be included in the first process M1, and the third coupling step F3 and the third removing step Q3 may be included in the second process M2. The first process M1 may be a FAB (fabrication facility) process, and the second process M2 may be a MOD (Module) process.

In the method S1 for manufacturing a display device according to the embodiment, the display panel 10, the panel support film 31 and the adhesive layer 32 are formed in the FAB process that is the first process M1, and the lower functional member 33 is formed in the MOD process that is the second process M2.

For example, in the method S1 for manufacturing a display device according to the embodiment, since the attachment process of the adhesive layer 32 is performed in the first process M1 that is the FAB process, the carrier film CRF may not be required. Also, in case that the display panel 10 is transported to a space for performing the second process M2 for attaching the lower functional member 33 after the attachment of the adhesive layer 32, the second liner LNR2 may replace the role of the carrier film CRF. For example, the second liner LNR2 may protect the display panel 10 and the panel support film 31 and prevent permeation of particles.

The first liner LNR1 may be removed in the second removing step Q2 of the first process M1 in the method S1 for manufacturing a display device according to the embodiment. In the second coupling step F2 of the first process M1, the second liner LNR2 and the adhesive layer 32 are bonded to the display panel 10 and the panel support film 31. Afterwards, the display panel 10 may be transported, stored and processed from the first process M1 to the second process M2 in a state that the second liner LNR2 is attached thereto. The second liner LNR2 may be removed in the third removing step Q3 of the second process M2. In the third coupling step F3 of the second process M2, the lower functional member 33 is coupled to the display panel 10 and the panel support film 31 by the adhesive layer 32.

According to the method S1 for manufacturing a display device according to the embodiment, since the carrier film CRF is not required, its material cost may be saved, and processes such as the first coupling step F1′ and the first removing step Q1′ of the method S1′ for manufacturing a display device according to the comparative embodiment may be deleted, whereby process efficiency may be improved.

Other embodiments of a method for manufacturing a display device according to one embodiment will be described. In the following embodiment, the same reference numerals will be given to the same elements as those of the previous embodiment, a redundant description will be omitted or simplified, and the description will be based on differences from the previous embodiment.

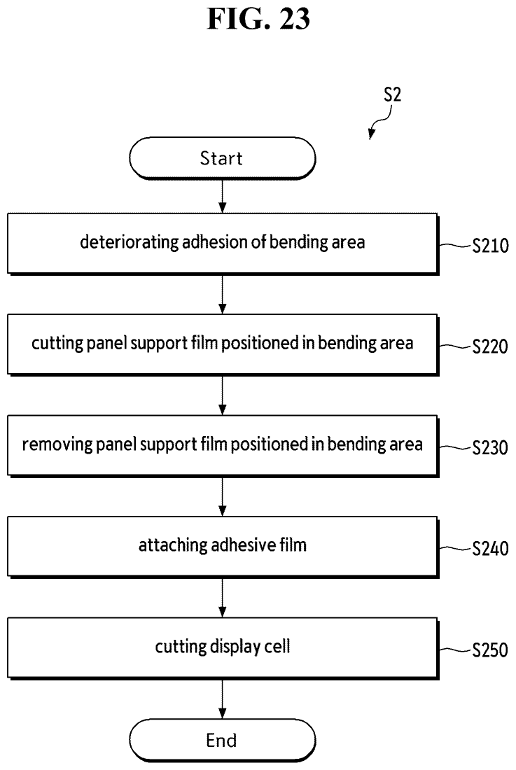

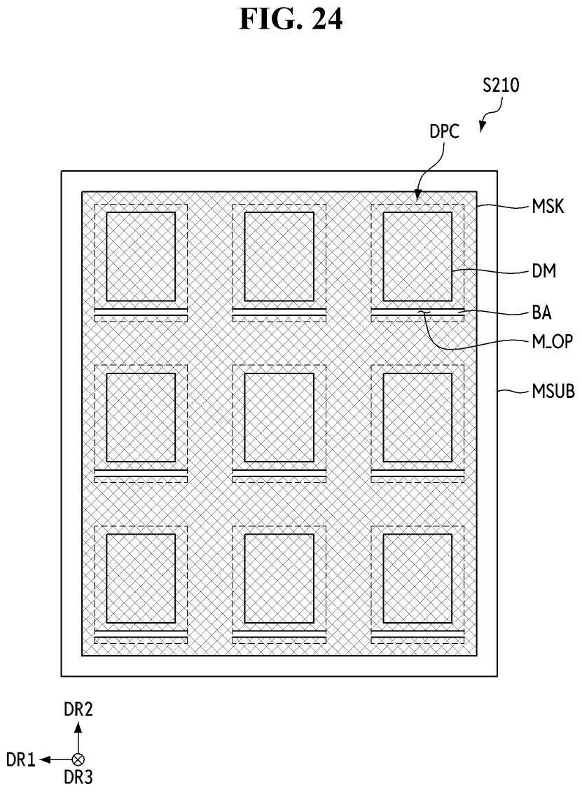

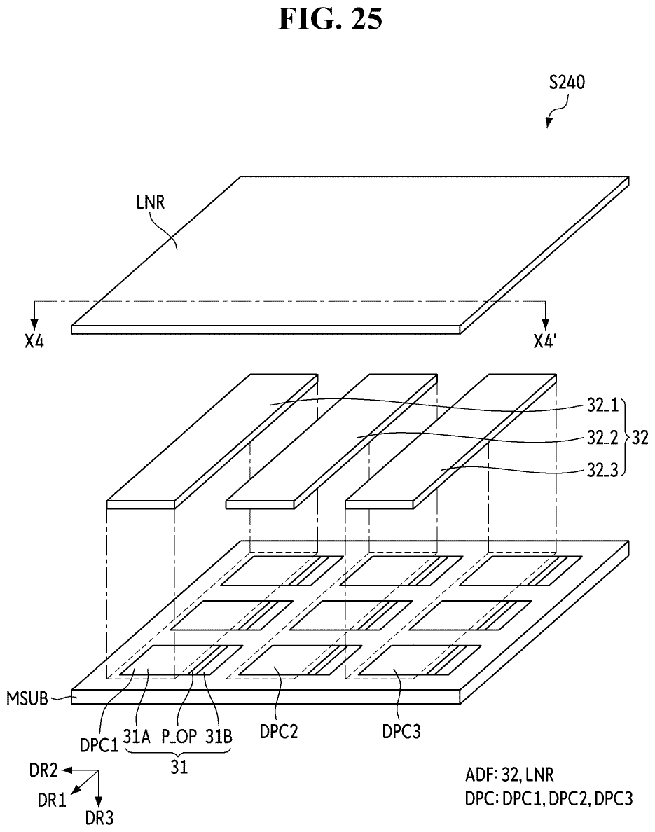

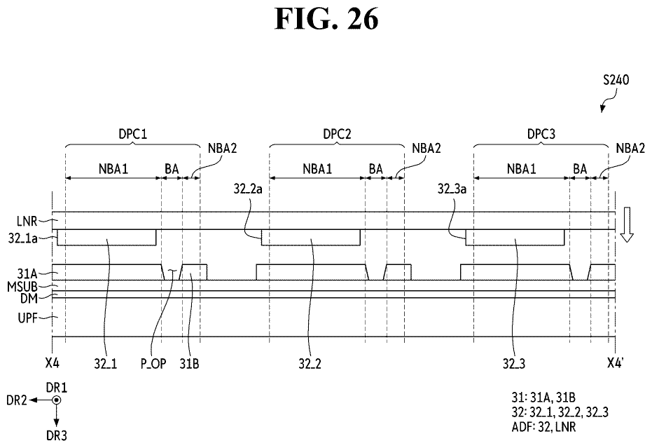

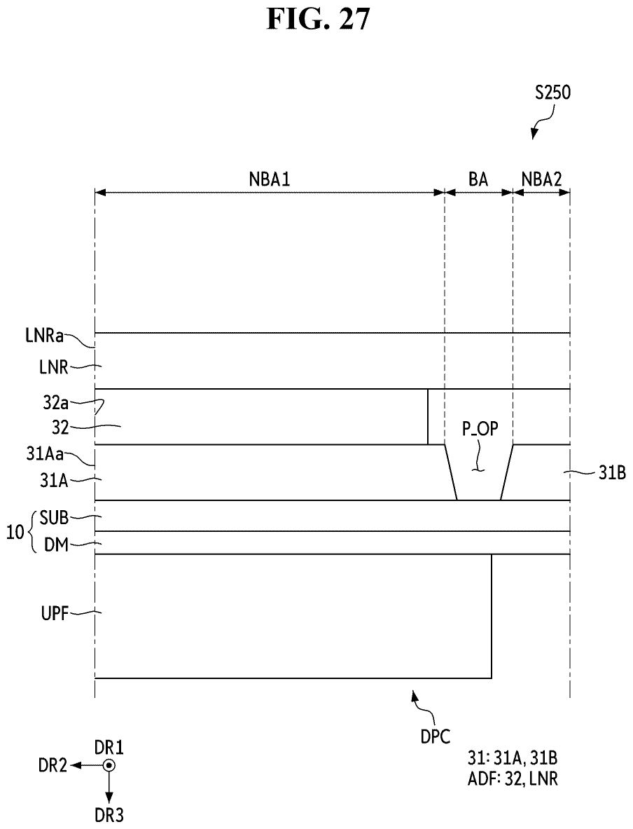

FIG. 23 is a schematic flow chart illustrating a method for manufacturing a display device according to another embodiment. FIG. 24 is a schematic plan view illustrating step S210 of FIG. 23. FIG. 25 is a perspective view illustrating step S240 of FIG. 23. FIG. 26 is a schematic cross-sectional view illustrating step S240 of FIG. 23. FIG. 27 is a schematic cross-sectional view illustrating step S250 of FIG. 23.

Referring to FIGS. 23 to 27, the method S2 for manufacturing a display device according to the embodiment differs from the method S1 for manufacturing a display device according to one embodiment described with reference to FIG. 7 in that the step S250 of cutting a display cell proceeds after the step S240 of attaching an adhesive film.

The method S2 for manufacturing a display device according to the embodiment may include step S210 of deteriorating adhesion of the bending area, step S220 of cutting the panel support film positioned in the bending area, step S230 of removing the panel support film positioned in the bending area, step S240 of attaching the adhesive film, and step S250 of cutting the display cell.

As shown in FIG. 24, in the step S210 of the deteriorating adhesion of the bending area, the mask MSK may be disposed over multiple display cells DPC disposed on the mother substrate MSUB. The mask MSK may include multiple mask openings M_OP that overlap the bending area BA of multiple display cells DPC.

The energy source U (see FIG. 11) of the energy irradiation device USR (see FIG. 11) may change physical properties of the interface between the display panel 10 and the panel support film 31 or the adhesive element disposed on the interface through the mask opening M_OP, thereby deteriorating adhesion of the adhesive element.

The step S220 of the cutting the panel support film positioned in the bending area and the step S230 of removing the panel support film positioned in the bending area are substantially the same as the step S130 of the cutting the panel support film positioned in the bending area and the step S140 of the removing the panel support film positioned in the bending area in the method S1 for the manufacturing the display device according to the embodiment described with reference to FIG. 7 and thus their description will be omitted.

In the step S240 of the attaching the adhesive film, the adhesive film ADF may be attached onto multiple display cells DPC. The adhesive film ADF may be attached onto the rear surface (e.g., the upper surface in the drawing) of the panel support film 31.

The adhesive film ADF may include an adhesive layer 32 and a liner LNR. The adhesive film ADF may be a patterned adhesive film. The adhesive film ADF may be a film to which the patterned adhesive layer 32 is attached onto the liner LNR. For example, the adhesive film ADF may be a film to which multiple adhesive layers 32 extended in the first direction DR1 and spaced apart from each other in the second direction DR2 are attached to the liner LNR.

The adhesive layer 32 may include a first adhesive layer 32_1, a second adhesive layer 32_2, and a third adhesive layer 32_3.

Each of the first adhesive layer 32_1, the second adhesive layer 32_2, and the third adhesive layer 32_3 may be extended in the first direction DR1. The first adhesive layer 32_1 may be disposed on as of the second adhesive layer 32_2 in the second direction DR2, and the second adhesive layer 32_2 may be disposed on as of the third adhesive layer 32_3 in the second direction DR2.

The first adhesive layer 32_1 may be disposed on a first display cell group DPC1, the second adhesive layer 32_2 may be disposed on a second display cell group DPC2, and the third adhesive layer 32_3 may be disposed on a third display cell group DPC3.

The first display cell group DPC1 may be a set of display cells DPC spaced apart from each other in the first direction DR1, the second display cell group DPC2 may be a set of display cells DPC spaced apart from each other in the first direction DR1, and the third display cell group DPC3 may be a set of display cells DPC spaced apart from each other in the first direction DR1. The first display cell group DPC1 may be disposed on as of the second display cell group DPC2 in the second direction DR2, and the second display cell group DPC2 may be disposed on as of the third display cell group DPC3 in the second direction DR2.

As shown in FIG. 26, in the step S240 of the attaching the adhesive film, an end portion 32_1a of the first adhesive layer 32_1, an end portion 32_2a of the second adhesive layer 32_2, and an end portion 32_3a of the third adhesive layer 32_3 may be more protruded than the boundary of the first non-bending area NBA1, respectively. Therefore, a cutting margin may be ensured in the step S250 of cutting the display cell, which is a subsequent process.

The liner LNR may be disposed over multiple display cells DPC.

In the step S250 of the cutting the display cell, the display cells DPC may be cut and separated from the mother substrate MSUB by the first cutting device LSR1 (see FIG. 8) in the same manner as the step S110 of cutting the display cell in the method S1 for manufacturing a display device according to one embodiment described with reference to FIG. 7. For example, the liner LNR and the adhesive layer 32 may be cut together.

Therefore, the boundary of an end 32a of the adhesive layer 32 may be matched with the boundary of an end LNRa of the liner LNR and the boundary of an end 31Aa of the first panel support film 31A of the panel support film 31.

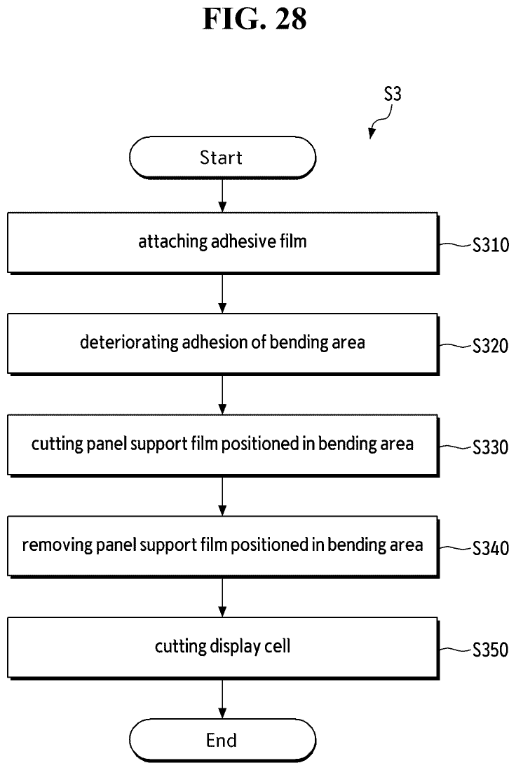

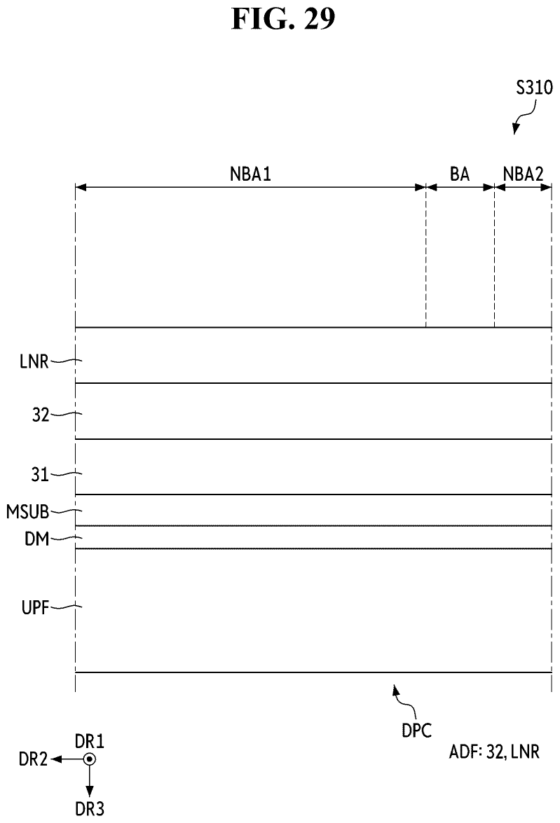

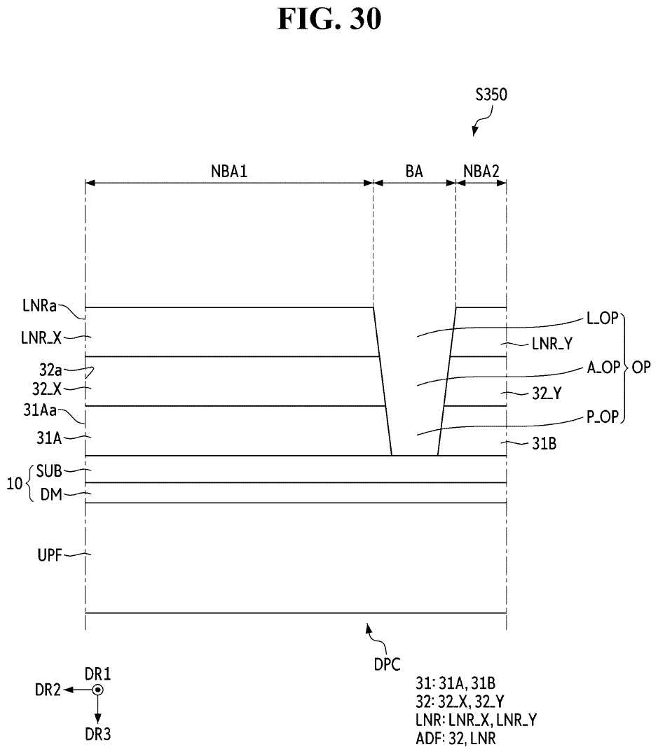

FIG. 28 is a schematic flow chart illustrating a method for manufacturing a display device according to another embodiment. FIG. 29 is a schematic cross-sectional view illustrating step S310 of FIG. 28. FIG. 30 is a schematic cross-sectional view illustrating step S350 of FIG. 28.

Referring to FIGS. 28 to 30, a method S3 for manufacturing a display device according to the embodiment differs from the method S2 for the manufacturing the display device according to another embodiment described with reference to FIG. 23 in that the step S310 of attaching an adhesive film proceeds earlier than the step S320 of deteriorating adhesion of the bending area and the adhesive layer 32 of the adhesive film ADF is disposed on the entire surface.

The method S3 for the manufacturing the display device according to the embodiment may include step S310 of attaching the adhesive film, step S320 of deteriorating adhesion of the bending area, step S330 of cutting the panel support film positioned in the bending area, step S340 of removing the panel support film positioned in the bending area, and step S350 of cutting the display cell.

As shown in FIG. 29, in the step S310 of the attaching the adhesive film, the adhesive film ADF including the liner LNR and the adhesive layer 32 may be attached onto the panel support film 31 disposed on the rear surface of the mother substrate MSUB.

In the method S3 for the manufacturing the display device according to the embodiment, the adhesive layer 32 and the liner LNR may be disposed over the entire plurality of display cells DPC. For example, in the method S2 for the manufacturing the display device according to another embodiment, the adhesive layer 32 shown in FIG. 26 may be disposed only on the first non-bending area NBA1, whereas in the method S3 for the manufacturing the display device according to the embodiment, the adhesive layer 32 may be disposed over the first non-bending area NBA1, the bending area BA and the second non-bending area NBA2.

The step S320 of the deteriorating adhesion of the bending area, the step S330 of cutting the panel support film positioned in the bending area, the step S340 of the removing the panel support film positioned in the bending area and the step S350 of the cutting the display cell are the same as the step S210 of the deteriorating adhesion of the bending area, the step S220 of the cutting the panel support film positioned in the bending area, the step S230 of the removing the panel support film positioned in the bending area and the step S250 of cutting the display cell in the method S2 for the manufacturing the display device according to another embodiment described with reference to FIG. 23, respectively, and thus their description will be omitted.

In the step S350 of the cutting the display cell in the method S3 for the manufacturing the display device according to the embodiment, the liner LNR and the adhesive layer 32 may be cut together in the same manner as the method S2 for the manufacturing the display device according to another embodiment described with reference to FIG. 23.

Therefore, the boundary of an end 32a of the adhesive layer 32 may be matched with the boundary of an end LNRa of the liner LNR and the boundary of an end 31Aa of the first panel support film 31A of the panel support film 31.

In the method S3 for manufacturing a display device according to the embodiment, since the adhesive layer 32 and the liner LNR are disposed over multiple display cells DPC and the dummy DUM (see FIG. 13) portion is removed together, an opening A_OP of the adhesive layer 32 and an opening L_OP of the liner LNR may be formed together with the opening P_OP of the panel support film 31.

The opening P_OP of the panel support film 31, the opening A_OP of the adhesive layer 32 and the opening L_OP of the liner LNR may be one opening OP communicated with one another. In other embodiments, a side of the opening A_OP of the adhesive layer 32 and a side of the opening L_OP of the liner LNR may be an inclined surface in the same manner as the side of the opening P_OP of the panel support film 31.

The adhesive layer 32 may include a first portion 32_X disposed on a side and a second portion 32_Y disposed on another side based on the opening A_OP, and the liner LNR may include a first portion LNR_X disposed on a side and a second portion LNR_Y disposed on another side based on the opening L_OP.

The display device 10 according to the above-described embodiments may be applied to various electronic devices 1000. The electronic device 1000 according to one embodiment may comprise the above-described display device 10 and may include a module or device having other additional functions in addition to the display device 10.

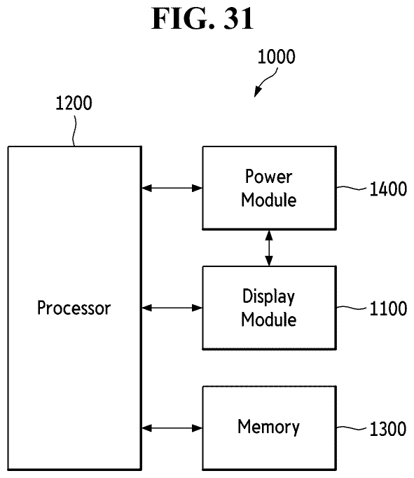

FIG. 31 is a schematic block diagram of an electronic device according to one embodiment.

Referring to FIG. 31, the electronic device 1000 according to one embodiment may include a display module 1100, a processor 1200, a memory 1300, and a power module 1400.

Processor 1200 may include at least one of central processing unit (CPU), application processor (AP), graphic processing unit (GPU), communication processor (CP), image signal processor (ISP), or controller.

Memory 1300 may store data information necessary for the operation of the processor 1200 or display module 1100. When the processor 1200 executes the application stored in the memory 1300, the image data signal and/or input control signal is transmitted to the display module 1100, and the display module 1100 can process the provided signal and output the image information through the display screen.

The power module 1400 may include a power supply module, such as a power adapter or battery device, and a power conversion module that converts the power supplied by the power supply module to generate the power required for the operation of the electronic device 1000.

At least one of each of the elements of the above-described electronic device 1000 may be included within the display device 10 according to the embodiments described above. Some of the individual modules functionally contained within a module may be contained within the display device 10 and others may be provided separately from the display device 10. For example, the display device 10 may include the display module 1100, and the processor 1200, memory 1300 and power module 1400 may be provided in the form of another device within the electronic device 1000 that is not the display device 10.

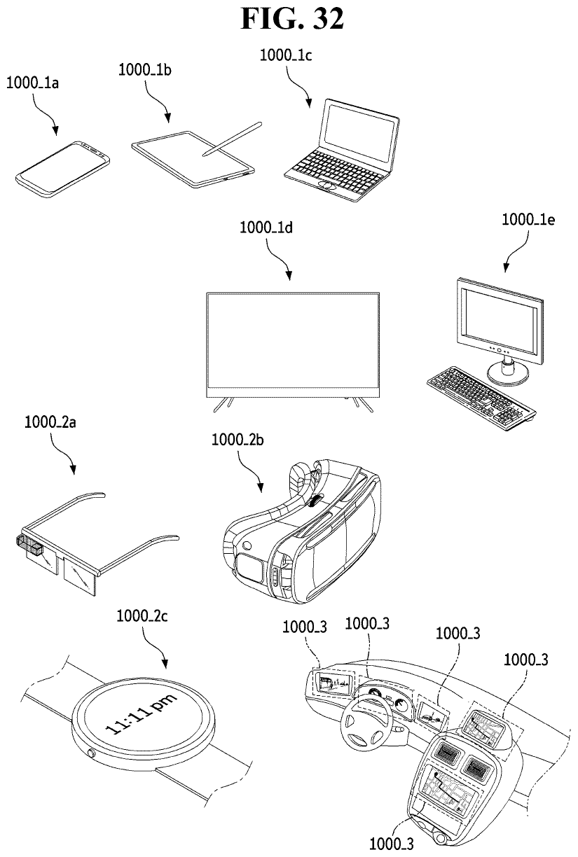

FIG. 32 is a schematic diagram of an electronic device according to various embodiments.

Referring to FIG. 32, the various electronic devices 1000 to which the display device 10 is applied according to embodiments are not only electronic devices for image display such as smartphones 1000_1a, tablet PCs 1000_1b, laptops 1000_1c, TVs 1000_1d, desk monitors 1000_1e, but also wearable electronic devices 1000 including display modules such as smart glasses 1000_2a, head-mounted displays 1000_2b, smart watches 1000_2c, and vehicle electronics (1000_3) including display modules such as CID (Center Information Display) placed on the instrument panel of the car, center fascia, and dashboard, and room mirror display.

In concluding the detailed description, those skilled in the art will appreciate that many variations and modifications can be made to the preferred embodiments without substantially departing from the principles of the disclosure. Therefore, the disclosed preferred embodiments of the invention are used in a generic and descriptive sense only and not for purposes of limitation.

What is claimed is:

1. A method for manufacturing a display device, the method comprising:
attaching a panel support film onto a display panel including a bending area;
removing a portion of the panel support film, which is disposed in the bending area; and
attaching an adhesive film onto the panel support film,
wherein the adhesive film includes an adhesive layer and a liner disposed on the adhesive layer.

2. The method of claim 1, wherein
the panel support film includes a first opening disposed in the bending area, and
the adhesive layer does not overlap the first opening in a thickness direction.

3. The method of claim 2, wherein
a side of the first opening is an inclined surface.

4. The method of claim 1, further comprising cutting a display cell including the display panel, wherein
the cutting of the display cell is performed before the attaching of the panel support film, and
an end of the adhesive layer is positioned more inward than an end of the display panel.

5. The method of claim 1, further comprising cutting a display cell including the display panel, wherein
the cutting of the display cell is performed after the attaching of the adhesive film, and
a boundary of an end of the adhesive layer is aligned with a boundary of an end of the display panel.

6. The method of claim 1, wherein
the attaching of the adhesive film is performed before the removing of the portion of the panel support film, which is disposed in the bending area, and
the adhesive layer is removed together with the panel support film in the removing of the portion of the panel support film, which is disposed in the bending area.

7. A method for manufacturing a display device, the method comprising:
manufacturing a display panel; and
attaching a module to the display panel, wherein
the manufacturing of the display panel includes attaching a panel support film onto the display panel and attaching an adhesive film onto the panel support film, and
the attaching of the module to the display panel includes attaching a lower functional member onto the adhesive film.

8. The method of claim 7, wherein
the adhesive film includes an adhesive layer and a liner disposed on the adhesive layer, and
the liner is removed in the attaching of the lower functional member.

9. The method of claim 7, wherein
the attaching of the panel support film and the attaching of the adhesive film, which are included in a first process, are performed in a continuous process.

10. The method of claim 9, wherein
the attaching of the panel support film and the attaching of the adhesive film, which are included in the first process, are performed in a clean room.

11. The method of claim 7, wherein
the manufacturing of the display panel and the attaching of the module to the display panel are performed in different spaces.

12. The method of claim 11, wherein
the manufacturing of the display panel and the attaching of the module to the display panel are performed by different subjects.

13. A display element comprising:
a display panel including a bending area;
a panel support film disposed on the display panel;
an adhesive layer disposed on the panel support film; and
a liner disposed on the adhesive layer,
wherein boundaries of an end of the panel support film, an end of the adhesive layer and an end of the liner are aligned with one another.

14. The display element of claim 13, wherein
the panel support film includes a first opening disposed in the bending area, and
the adhesive layer does not overlap the first opening in a thickness direction.

15. The display element of claim 14, wherein
a side of the first opening is an inclined surface.

16. The display element of claim 14, wherein
the liner overlaps the first opening in the thickness direction.

17. The display element of claim 14, wherein
the adhesive layer includes a second opening communicated with the first opening, a first portion disposed on a side of the second opening, and a second portion disposed on another side of the second opening.

18. The display element of claim 17, wherein
a side of the second opening is an inclined surface.

19. The display element of claim 18, wherein
the liner includes a third opening communicated with the second opening, a third portion disposed on a side of the third opening, and a fourth portion disposed on another side of the third opening.

20. The display element of claim 14, wherein
the adhesive layer is disposed on a side of the first opening, and is not disposed on another side of the first opening.

21. An electronic device comprising a display device manufactured by the method of claim 1.

22. An electronic device comprising a display device manufactured by the method of claim 7.
